(19) United States
(12) Patent Application Publication
(10) Pub. No.: US 2026/0276731 A1
(43) Pub. Date: Sep. 17, 2026

(54) Battery Self-Discharge Current Measurement and Monitoring with Parallel Cell Group

(71) Applicant: Chaojiong Zhang, College Station, TX (US)

(72) Inventor: Chaojiong Zhang, College Station, TX (US)

(21) Appl. No.: 19/167,454

(22) PCT Filed: Jul. 3, 2024
(86) PCT No.: PCT/US2024/036631

§ 371 Date: Sep. 22, 2025

Related U.S. Application Data
(60) Provisional application No. 63/560,645, filed on Mar. 2, 2024.
(60) Provisional application No. 63/571,581, filed on Mar. 29, 2024.
(60) Provisional application No. 63/633,789, filed on Apr. 14, 2024.
(60) Provisional application No. 63/662,192, filed on Jun. 20, 2024.

(51) Int. Cl. G01R 31/396; G01R 31/382; G01R 31/389; H01M 10/42; H02J 7/52

(52) U.S. Cl. CPC G01R 31/396; G01R 31/382; G01R 31/389; H01M 10/4285; H02J 7/52

(57) ABSTRACT

Methods and apparatuses are provided for measuring self-discharge current I_{sd} of cells and for using differential self-discharge current of paralleled cells as a quality control (QC) criterion. For cells in a group that are connected in parallel, current I_{b}#, which represents the current through the corresponding cell# in the group, may be measured, and self-discharge current of at least one cell (denoted as I_{sd}#) may be calculated based on a corresponding I_{b}# in various ways depending on whether the group of cells are connected to a power supply and which kind of power supply. The current I_{b}# may be used as a standard for cell quality judgment and/or cell classification, which is simpler, faster and cheaper than using self-discharge current as a QC criterion.

### CROSS-REFERENCE TO RELATED APPLICATIONS

This is a national-stage application of International Application No. PCT/US2024/036631 filed on 3 Jul. 2024, which was published as International Pub. No. WO 2025/116980 A1. This application claims priority to and the benefit of U.S. Provisional Patent Application Nos. 63/662,192 filed 20 Jun. 2024 titled “Galvanostatic Battery Self-Discharge Current Measurement and Self-Discharge Measurement/Monitoring with Parallel Cell Group,” 63/633,789 filed 14 Apr. 2024 titled “Using Current of Cells in a Parallel Battery Group at Open-Circuit Condition as a QC Method,” 63/571,581 filed 29 Mar. 2024 titled “Using Current of Cells in a Parallel Battery Group at Open-Circuit Condition as a QC Method,” 63/560,645 filed 2 Mar. 2024 titled “Measuring Self-Discharge of Batteries,” and International Patent Application No. PCT/US2023/081285 filed on 28 Nov. 2023 titled “Analyzer and Method for Determining Self-Discharge of Batteries,” each of which is incorporated by reference in its entirety for all purposes. This application is related to the present inventor's International Patent Application No. PCT/US2020/062548 A2 filed on 30 Nov. 2020, which was published as International Patent Application Pub. No. 2021/113161 A2 and titled “System for Forming and Testing Batteries in Parallel and in Series,” which is incorporated by reference in its entirety for all purposes. This application is also related to the present inventor's International Patent Application No. PCT/US2022/021643 filed on 24 Mar. 2022, which was published as International Pub. No. WO 2023/027766 A1 and titled “System for Determining Battery Parameters,” and which is incorporated by reference in its entirety for all purposes.

### BACKGROUND OF THE INVENTION

### 1. Field of the Invention

This patent application pertains to forming, testing and sorting batteries, particularly to high precision, high speed and low cost battery testing technology, particularly to measuring self-discharge for batteries, and more particularly to evaluating quality of batteries.

### 2. Description of the Related Art

One of the important characteristics of a battery is its leakage current or self-discharge current. Leakage current is affected by battery quality, state of charge and temperature. One method for measuring leakage current is to hold a battery at a constant voltage and measure a charging current when the current is stabilized to a constant value. A Self-Discharge Analyzer from Keysight Technologies, Inc. is believed to use this method. This method is very sensitive to the fluctuation of the open-circuit voltage (OCV) of the battery being tested, and the OCV is particularly sensitive to the fluctuation of temperature, even if a relatively expensive potentiostat with high precision and high stability is used. It is difficult to achieve the stability of the OCV required for self-discharge measurement. For example, a voltage sourcing stability of 3 μV peak may cause a disturbance of the battery's electrochemical system and make it difficult to get real leakage current. Therefore, the measurement time of this method is still relatively long, such as a few hours, and the accuracy of this method is relatively poor. It is further believed that Keysight's Self-Discharge Analyzer requires one channel per battery.

An indirect method is to measure a voltage drop of a battery at open circuit over a period of time. This method may take a very long time (several days or even weeks) to do and still does not provide a leakage current value, but it is popular among battery manufacturers because it does not require expensive equipment. This method assumes that capacitance of all cells is the same within a tolerable precision.

It is desired to have a method that can measure self-discharge (SD) of batteries quickly, precisely and at a reasonable cost for making batteries and for using batteries such as for electrical vehicles and battery energy storage systems. Also, it is desired to have a method that can qualify each cell in a paralleled cell group instantly and precisely.

### SUMMARY OF THE INVENTION

Methods and apparatuses are provided for measuring and monitoring self-discharge current of cells connected in parallel, specifically in a galvanostatic way, and for using differential self-discharge current of paralleled cells as a quality control (QC) criterion in battery testing, formation and manufacture. A battery may contain one or more cells, and a battery may also be used in a battery group.

A method for measuring self-discharge of cells in a group under a same voltage is disclosed that comprises the steps of: measuring current Ib# for at least one cell in the group of cells, wherein Ib# represents the current through the corresponding cell#; and evaluating the self-discharge of at least one cell in the group of cells based on the current Ib#, preferably using abnormal distributed current through cell# (Ib#) of the group of cells as a criterion for cell safety judgment. The group of cells are preferably not connected to any power supply to keep in open circuit, and preferably allowing enough time for the group of cells to reach balance status prior to measuring current Ib# for at least one cell in the group of cells. The method preferably includes using the Ib# value as a standard for cell quality judgment and/or cell classification for evaluating the self-discharge of at least one cell in the group based on the current Ib#. The cells in the group are preferably connected in parallel with each other cell, where a constant current (I_{O}) is preferably applied to the group of cells prior to measuring current Ib# for at least one cell in the group of cells.

The self-discharge current of at least one cell# (denoted as Isd#) is preferably calculated from an equation: Isd#=AIsd−(Ib#−I_{O} In) on the assumption that a difference of dynamic capacitance (DNC) of the cells can be ignored in calculation of self-discharge current (Isd) and AIsd is known, wherein AIsd represents average self-discharge current of all cells in the group and n represents a number of cells in the group. An absolute value of I_{O} is preferably controlled to be equivalent to that of total self-discharge current (TIsd) of the group of cells, and assuming TIsd is known, the equation becomes: Isd#=−Ib# on the assumption that a difference of dynamic capacitance (DNC) of the cells can be ignored in calculation of self-discharge current.

The method preferably includes applying a constant voltage to the group of cells to make a current flow through the group of cells, preferably where evaluating the self-discharge of at least one cell in the group of cells based on the current Ib#, and preferably calculating self-discharge current of at least one cell (denoted as Isd#) from the equation: Isd#=−1b#. The method for evaluating the self-discharge of at least one cell in the group based on the current Ib# preferably includes using measured or statistically obtained average self-discharge current AIsd of the parallel group to get self-discharge current (Isd#) of at least one cell#, according to Isd#=AIsd−Ib# derived from Ib#=AIsd−Isd#.

A method for measuring self-discharge of cells in a group under a same voltage is disclosed that comprises the steps of: measuring current Ib# for at least one cell in the group of cells, wherein Ib# represents the current through the corresponding cell#; and evaluating the self-discharge of at least one cell in the group of cells based on the current Ib#. The cells in the group are preferably connected in series and each cell of the group is preferably connected to an equalizer to keep the cells under a same voltage with equalizers on, where each equalizer preferably has a fully bidirectional charge/discharge channel with at least two current ranges, and where at least one current range is low enough to be capable of measuring self-discharge current (SDC), evaluating the self-discharge of at least one cell in the group of cells based on the current Ib# and calculating self-discharge current of at least one cell# (denoted as Isd#) based on measured current Ib# and current flowing through combinations of the cell and a corresponding equalizer, where the combinations are connected in series.

A method is disclosed for measuring self-discharge current (Isd) of cells in a group that are connected in series with an equalizer for each cell. The method includes allowing enough time for a group of cells connected in series to reach balance status, where each cell of the group is connected to an equalizer to keep the cells under a same voltage with equalizers on, where each equalizer has a fully bidirectional charge/discharge channel with at least two current ranges, and where at least one current range is low enough to be capable of measuring self-discharge current (SDC); measuring current Ieqp# for at least one equalizer in response to the cells' reaching balance status, wherein Ieqp# represents the current flowing through equalizer# connected to corresponding cell#; and calculating self-discharge current of at least one cell# (denoted as Isd#) from an equation: Isd#=−Ieqp#. The cells in the group that are connected in series with an equalizer for each cell comprises parallel cell groups (PCGs) in a group that are connected in series with an equalizer for each PCG and Ieqp# represents the current flowing through equalizer# connected to corresponding PCG#.

An auto analyzer is disclosed for evaluating batteries that includes a power supply; one or more processors; and one or more storage media storing instructions executable by the one or more processors, wherein the instructions, when executed, cause the auto analyzer to perform operations to execute the methods described above. The power supply preferably comprises a battery testing apparatus that includes a normal battery operating as a standard battery (SB); a constant current source configured to apply a controllable current through the normal battery (Isb) that is equal to its self-discharge current, whereby a voltage of the normal battery is held constant at its open-circuit voltage (OCV); and a positive terminal (IOH) and a negative terminal (IOL) are configured to connect a battery under test therebetween, where the voltage between the terminal (IOH) and the terminal (IOL) is kept at a constant value approximately equal to the voltage of the SB within a desired precision.

An equalizer plus (EQP) of a battery is disclosed that includes a control circuit configured to apply a controllable current to a normal battery as a standard battery (SB) inside the EQP, where the current through the SB (Isb) is controlled to be equal to its self-discharge current, whereby a voltage of the SB is kept constant at its open-circuit voltage (OCV); two terminals (IOH) and (IOL) for connecting a battery under test therebetween, where the terminal (IOH) is connected to an end of a branch where the SB is located, and the voltage between the terminal (IOH) and the terminal (IOL) is kept at a constant value approximately equal to the voltage of the SB within a desired precision. The terminal (IOL) is connected to the other end of the branch, and a fully bidirectional charge/discharge channel between the terminals (IOH) and (IOL) is included for measuring current, where the channel has at least two current ranges, and where at least one current range is low enough to be capable of measuring self-discharge current.

This summary is provided to introduce a selection of concepts in a simplified form that are further described herein in a detailed description. This summary is not intended to identify key factors or essential features of the claimed subject matter, nor is it intended to be used to limit the scope of the claimed subject matter. These and other features and advantages of the present invention will be described in, or will become apparent to those of ordinary skill in the art in view of, the following detailed description of example embodiments of the present invention.

### BRIEF DESCRIPTION OF THE DRAWINGS

These and other features of the disclosure will now be described with reference to drawings summarized below. The drawings and the associated description are provided to illustrate example embodiments of the disclosure and are not intended to limit the scope of the disclosure.

FIG. 1 is a simple equivalent circuit of a battery for self-discharge current (Isd). For a small voltage range, OCV drop rate dV/dt is proportional to Isd.

FIG. 2 is a block diagram of an example differential battery analyzer (DBA), according to the present disclosure.

FIG. 3 is a block diagram of another example DBA, according to the present disclosure.

FIG. 4 is a block diagram of yet another example DBA, according to the present disclosure.

FIG. 5 is a block diagram of an example universal differential battery analyzer (UDBA), according to the present disclosure.

FIG. 6 is a block diagram of another example universal differential battery analyzer (UDBA), according to the present disclosure.

FIG. 7 is a block diagram of yet another example DBA, according to the present disclosure.

FIG. 8 is an illustrative circuit for measuring differential voltage using the DBA, according to the present disclosure.

FIG. 9 is an illustrative circuit for measuring Isd by applying constant voltage equal to the OCV of the battery, which is called a potentiostatic method. This method is believed to be used by Keysight's Self-Discharge Analyzer.

FIG. 10 is an illustrative circuit for measuring Isd by applying constant current to the battery, according to the present disclosure.

FIG. 11 is an illustrative block flow diagram for a process for measuring Isd by applying constant current to the battery, according to the present disclosure, which is called a galvanostatic method.

FIG. 12 is an illustrative circuit for measuring Isd by applying constant current to the battery with the DBA, according to the present disclosure.

FIG. 13 is an illustrative circuit for measuring Isd of a group of batteries connected in parallel by applying constant current to the batteries with the DBA, according to the present disclosure.

FIG. 14 is another illustrative block flow diagram for a process for measuring Isd by applying constant current to the battery, according to the present disclosure.

FIG. 15 is another illustrative circuit for measuring Isd by applying constant current to the battery with the DBA, according to the present disclosure.

FIG. 16 is an illustrative block flow diagram for a process for measuring Isd without applying any current to the battery, according to the present disclosure, which is called a passive method.

FIG. 17 is an illustrative block flow diagram for a process for measuring self-discharge of cells in the group under same voltage, according to the present disclosure.

FIG. 18 is another illustrative block flow diagram for a process for measuring Isd of cells in a group that are connected in parallel, according to the present disclosure.

FIG. 19 is an illustrative circuit for using current of cells in a parallel group as a quality control method, according to the present disclosure.

FIG. 20 is an illustrative block flow diagram for a process for using current of cells in a parallel group as a quality control method, according to the present disclosure.

FIG. 21 is yet another illustrative block flow diagram for a process for measuring Isd of cells in a group that are connected in parallel, according to the present disclosure.

FIG. 22 is an illustrative circuit for a method for measuring self-discharge current (Isd) of cells in a group that are connected in series with an equalizer for each cell, according to the present disclosure.

FIG. 23 is an illustrative circuit for a method for measuring self-discharge current (Isd) of parallel cell groups (PCGs) that are connected in series with an equalizer for each PCG, according to the present disclosure.

FIG. 24 is an illustrative block flow diagram for a process for evaluating self-discharge of a battery by means of the DBA, according to the present disclosure.

FIG. 25 is an illustrative block flow diagram for a process for measuring direct current internal resistance of a battery by means of the DBA, according to the present disclosure.

### DETAILED DESCRIPTION OF THE EXEMPLARY EMBODIMENTS

Terminology used herein includes:
OCV: Open-circuit voltage of a battery
   R: Resistor
SDR: self-discharge resistance
SB: Standard battery, which can maintain a constant voltage over a very long time to serve as a reference voltage.
IM: circuit block for current measurement.
VM: circuit block for voltage measurement.
Iₜ, I_{O}, I_{sb}, I_{b}#, IH, IL, IOH, IOL: I represents current
V_{sb}, VH, VL: V represents voltage
V_{rf}: reference voltage
I_{sd}: self-discharge current
AI_{sd}: average self-discharge current of a group of batteries
DBA: Differential battery analyzer
UDBA: Universal differential battery analyzer
GST: Galvanostat to provide controlled current output.
PST: Potentiostat to provide controlled voltage output
SW#: switch
Mux: multiplexer

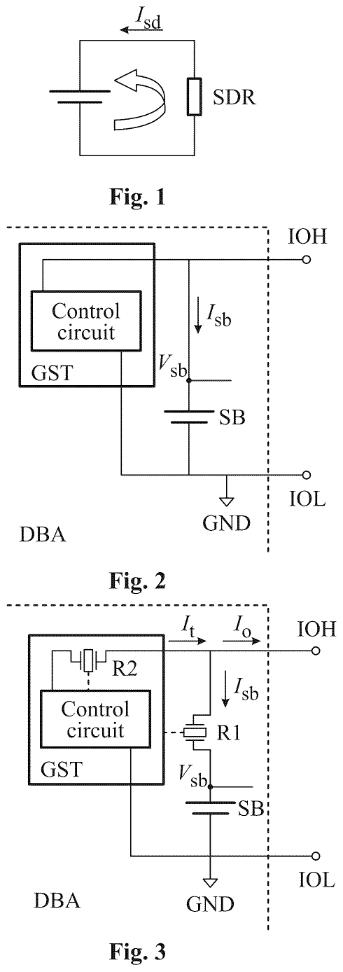

FIG. 1 illustrates a simple equivalent circuit of a battery for self-discharge current (Isd) according to aspects of the present disclosure. As shown in FIG. 1, for a small voltage range, OCV drop rate dV/dt is proportional to Isd, where Isd is usually a negative value.

FIG. 2 is a block diagram showing an example differential battery analyzer (DBA), according to the present disclosure. The DBA provides a reference voltage using a normal battery as a standard battery (SB). In this DBA, a control circuit configured to apply a controllable current is connected to a normal battery. A battery under test may be connected between terminals (IOH) and (IOL) of the DBA. In this DBA, the terminal (IOH) is connected to an end of a branch where the SB is located and the terminal (IOL) is connected to the other end of the branch. When the current through the normal battery (denoted as Isd) is controlled to make Isd equal to self-discharge current (denoted as Isd) of the SB, the voltage of the SB (denoted as Vsb) will be kept constant at its open-circuit voltage (OCV), whereby the voltage between the terminal (IOH) and the terminal (IOL) will be kept at a constant value approximately equal to the voltage Vsb within a desired precision. It can be seen that the use of the constant current method or galvanostatic method described herein to maintain the voltage of the standard battery and the voltage of the battery under test, is different from a potentiostatic (i.e. constant voltage) method of the prior art. The galvanostatic method has the advantages of low noise, low ripple, insensitivity to temperature changes, and little change in the SOC (State of Charge) and OCV of the battery.

In some examples, a control circuit configured to apply a controllable current may include a galvanostat (GST). In such examples, the output current from the GST is controlled via a control unit therein on the basis of feedback from a current sensor (eg. R1, R2). In some examples, such battery under test may include a group of batteries connected in parallel. The DBA described herein can maintain the standard battery voltage by making the controllable current through the SB equal to absolute value of self-discharge current of the SB. Thus, it is possible to control the constant voltage of the battery under test and measure the self-discharge thereof.

FIG. 3 is a block diagram showing another example DBA, according to the present disclosure. As shown in FIG. 3, the DBA may further comprise a first current sensor (denoted as R1) outside the GST. In some examples, the current sensor R1 is connected to the SB in series for measuring the current Isd, whereby the controllable current (It) from the DBA may be controlled by feedback from the current sensor R1. In some examples, the DBA may further comprise a second current sensor (denoted as R2) inside the GST. In some examples, the current sensor R2 is for measuring the current It directly, whereby the current It may be controlled by feedback from the current sensor R2. It is worth noting that the DBA may comprise only one of the current sensors R1 and R2 or both.

In some examples, when a battery is connected to the DBA via the terminals (IOH) and (IOL), the equation It=I_{O}+Isb will be satisfied, wherein I_{O} represents the current flowing to the terminal (IOH). Accordingly, the current I_{O} may be following to keep the potential of the terminal (IOH).

In some examples, a normal battery may include a secondary rechargeable battery, instead of a dedicated special primary (non-rechargeable) standard battery. In some examples, the normal battery may include a lithium ion battery. In some examples, a normal battery may have the same type as the battery under test. When using the same type of battery as the battery under test as the standard battery, the influence of temperature on the battery can be canceled or eliminated. A normal battery may comprise a secondary rechargeable battery.

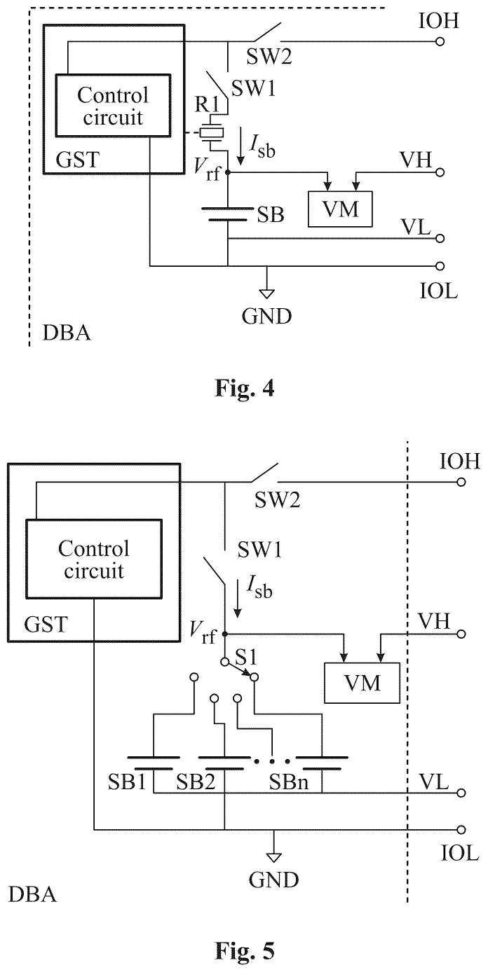

FIG. 4 is a block diagram of yet another example DBA, according to the present disclosure. As shown in FIG. 4, the DBA may further comprise another two terminals (VH) and (VL) and a circuit block for voltage measurement (VM). Alternatively, the DBA may further comprise a first switch (denoted as SW1) and a second switch (denoted as SW2) as shown in FIG. 4. The switch SW1 may connect to the current sensor R1 serially and the switch SW2 may be located to connect or disconnect the current I_{O}. When a battery being tested is connected to the DBA via the terminals (VH) and (VL) and both SW1 and SW2 (if they exist) are kept on, the VM will measure the difference between the voltage of the battery under test and the reference voltage (denoted as Vrf), which is determined on the basis of the voltage Vsb. Thus, the DBA described above can be used for high-precision battery voltage measurement/comparison through differential voltage measurement by means of applying a constant current to a normal battery to provide a constant voltage as a reference voltage. In some examples, the DBA may have multiple reference voltage ranges. A programmable reference voltage can be provided through various methods. In some examples, the voltage Vrf can be selected as one of a plurality of normal batteries above with different OCVs.

FIG. 5 is a block diagram showing an example universal differential battery analyzer (UDBA), according to the present disclosure. As shown in FIG. 5, the DBA, based on the description in FIG. 4 above, may further comprise another switch (denoted as S1) to select one from a plurality of normal batteries (such as SB1, SB2, SBn) with different OCVs. Thus, the voltage Vrf provided by the DBA can be changed with the selected battery.

In some examples, for a normal battery at nearly balanced status, the change of the current therethrough will cause voltage change thereof within a very small voltage range, wherein such current through the normal battery is usually very small so as to not interrupt the electrochemical balance of the battery. In some examples, such current may be at the level of leakage current of the normal battery. Under these circumstances, the voltage of the normal battery can change slowly with the current therethrough. Accordingly, the voltage Vrf will be changed when the voltage of the normal battery changes slowly. Although this method takes a long time to reach equilibrium to change the voltage Vrf, the obtained reference voltage range has the lowest electrical signal noise.

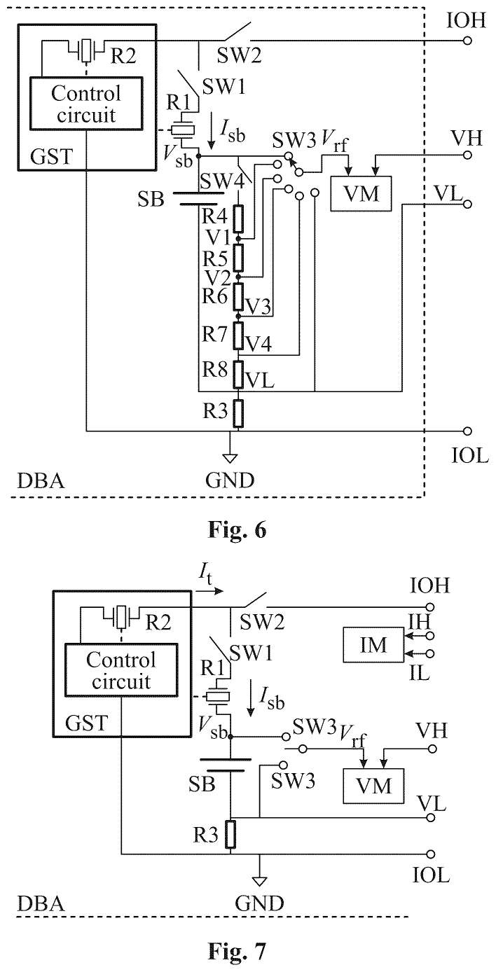

In some examples, the voltage Vrf can be selected as one of a plurality of reference voltages within a range not greater than a value of the voltage Vsb. FIG. 6 is a block diagram showing another example universal differential battery analyzer (UDBA), which provides a programmable reference voltage by dividing the voltage of the standard battery, according to the present disclosure. As shown in FIG. 6, the UDBA may further comprise a plurality of resistors (such as R4, R5, R6, R7, R8) connected serially with each other and in parallel with the branch where the SB is located. Each resistor has its respective reference voltage output terminal (such as V1, V2, V3, V4, VL) used for being selected via a multiplexer (denoted as SW3) connected to the VM described above. Therefore, a UDBA with multiple voltage ranges is obtained. In one embodiment, a voltage range includes 4.2±0.2V (Vsb range)/3.8±0.2V (corresponding to V1)/3.4±0.2V (corresponding to V2)/3.0±0.2V (corresponding to V3)/2.6±0.2V (corresponding to V4). In another embodiment, a voltage range includes 4.0±0.5V (corresponding to V1)/3.0±0.5V (corresponding to V2)/2.0±0.5V (corresponding to V3)/1.0±0.5V (corresponding to V4)/0.0±5.0V (VL range).

Alternatively, a switch (denoted as SW4) may be located in the branch where the divider resistors are connected serially with each other. SW4 can be turned off in Vsb range or VL range, that is, the branch of divider resistors can be cut off to reduce the noise level. The role of a DBA/UDBA in VL range is the same as that of a general VM. It should be noted that Vsb range has the lowest noise, and the noise when using voltage divider resistors is 2~3 times higher than that of Vsb range.

Alternatively, a grounding resistor (denoted as R3) may be connected between the SB and the terminal (IOL) to cancel or eliminate voltage fluctuations of ground (GND). Alternatively, one or more components of R1, R2, SW1 and SW2 may be eliminated.

There are advantages to using the UDBA described above. The reference voltage value can be quickly switched to obtain differential voltage measurements of different ranges, which is highly versatile and practical. Regular voltage ranging is for meeting the varied scales of voltage of the object under test, such as ±100V/±10V/±1/±0.1V/. Reference voltage range in this disclosure is different and unique, which is to meet a requirement for a different section of a voltage scale such as 0~5V. This is especially unique to be applied to a reference voltage from a standard battery. Examples include 4.0±0.5V/3.0±0.5V/2.0±0.5V/1.0±0.5V/0.0±0.5V in voltage scale of 0~4.5V.

In some examples, the DBA, based on the DBA described above, may further comprise another two terminals (IH) and (VL) connected to a circuit block for current measurement (IM). In these circumstances, a DBA with current reading terminals is provided.

FIG. 7 is a block diagram of yet another example DBA, according to the present disclosure. In terms of components of the DBA shown in FIG. 7, reference can be made to the above.

FIG. 8 is an illustrative circuit for measuring differential voltage using the DBA, according to the present disclosure. As shown in FIG. 8, a battery under test may be connected to the DBA described above via the terminals (VH) and (VL). Detailed descriptions of components of the DBA shown in FIG. 8 are provided above. In this way, a differential voltage representing a difference between the voltage Vrf and the voltage of the terminal (VH) can be measured by means of the VM inside the DBA. In some examples, such battery under test includes a group of batteries connected or not connected in parallel. Thus, this circuit can be used for differential voltage measurement for single or multiple batteries.

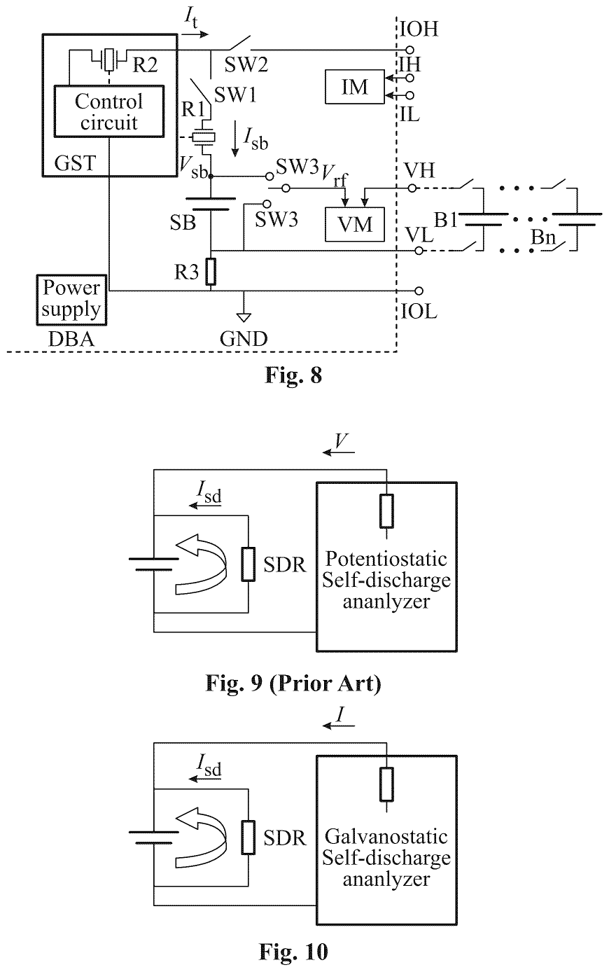

FIG. 9 is an illustrative circuit for measuring Isb by applying constant voltage equal to the OCV of a battery under test, which is called a potentiostatic method. This method is believed to be used in Keysight's Self-Discharge Analyzer.

FIG. 10 is an illustrative circuit for measuring Isd by applying constant current to a battery under test, according to the present disclosure. As shown in FIG. 10, a galvanostatic method is used to measure the self-discharge current of a battery. This disclosure illustrates a mechanism that uses the concept of dynamic capacitance to model a battery, preferably using this modeling during self-discharge current measurement. Using the above model, a galvanostat to provide controlled current output may give small currents I1 and I2 to a battery under test. By measuring (dV/dt)1 at I1 and (dV/dt)2 at I2 respectively, self-discharge current Isd and dynamic capacitance (DNC) of the battery under test can be calculated by solving the two equations: (dV/dt)1*DNC=I1+Isd, and (dV/dt)2*DNC=I2+Isd.

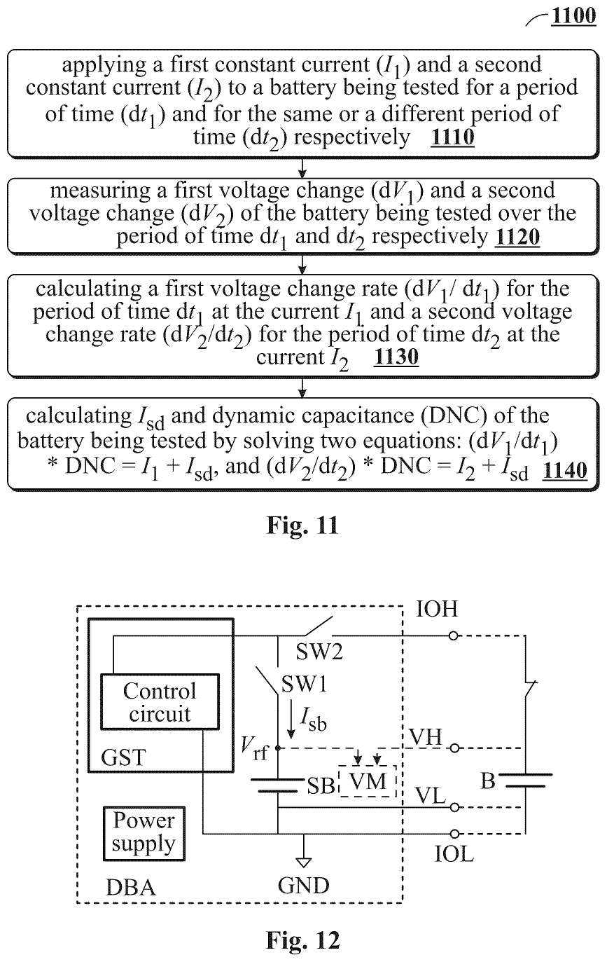

FIG. 11 depicts an example process 1100 for measuring Isd by applying constant current to a battery under test, in accordance with examples of the disclosure, which is called a galvanostatic method. For example, some or all of the process 1100 may be performed by one or more components in the DBA shown in FIGS. 2-FIG. 8, as described herein.

At operation 1110, the process may include applying a first constant current (I1) and a second constant current (I2) to a battery being tested for a period of time (dt1) and for the same or a different period of time (dt2), respectively. The current I1 and I2 are low enough not to interrupt the electrochemical balance of the battery being tested, but preferably high enough to accelerate the test.

In some examples, each of currents I1 and I2 is less than 100 ρA. In some examples, each of currents I1 and I2 is less than 50 μA. In some examples, each of currents I1 and I2 can be larger than 100 μA even in mA range depending on the dynamic capacity of the battery being tested. In some examples, such battery being tested includes a group of batteries connected in parallel.

At operation 1120, the process may include measuring a first voltage change (dV1) and a second voltage change (dV2) of the battery being tested over the period of time dt1 and dt2 respectively. In some examples, the two voltage changes may be measured by various means, such as the DBA with the VM described above. In some examples, each of the periods of time dt1 and dt2 is less than 24 hours.

At operation 1130, the process may include calculating a first voltage change rate (dV1/dt1) for the period of time dt1 at the current I1 and a second voltage change rate (dV2/dt2) for the period of time dt2 at the current I2.

At operation 1140, the process may include calculating Isd and dynamic capacitance (DNC) of the battery being tested by solving two equations: (dV1/dt1)*DNC=I1+Isd, and (dV2/dt2)*DNC=I2+Isd. It can be seen that using the current control (Galvanostatic) method described herein is different from the prior art voltage control (Potentiostatic) method to analyze self-discharge current of a battery. The galvanostatic method is useful especially in a battery formation procedure and in a battery testing procedure.

FIG. 12 is an illustrative circuit for measuring Isd by applying constant current to the battery with a DBA, according to the present disclosure. As shown in FIG. 12, a battery being tested is connected to the above DBA via the terminals (IOH) and (IOL). The DBA may be used to provide a first constant current I1 and a second constant current I2. As discussed above, a first voltage change and a second voltage change of the battery being tested over the periods of time dt1 and dt2 may be measured respectively. Then, Isd and dynamic capacitance of the battery being tested can be calculated by solving the two equations above.

In some examples, the DBA may further comprise another two terminals (VH) and (VL) and a circuit block for voltage measurement (VM) for measuring differential voltage between a reference voltage (Vrf) and the voltage of the battery being tested, as described in FIG. 4. In such examples, the voltage Vrf is determined on the basis of the voltage Vsb. As shown in FIG. 12, the battery being tested may be further connected to the DBA via the terminals (VH) and (VL), whereby the two voltage changes can be measured by means of the VM.

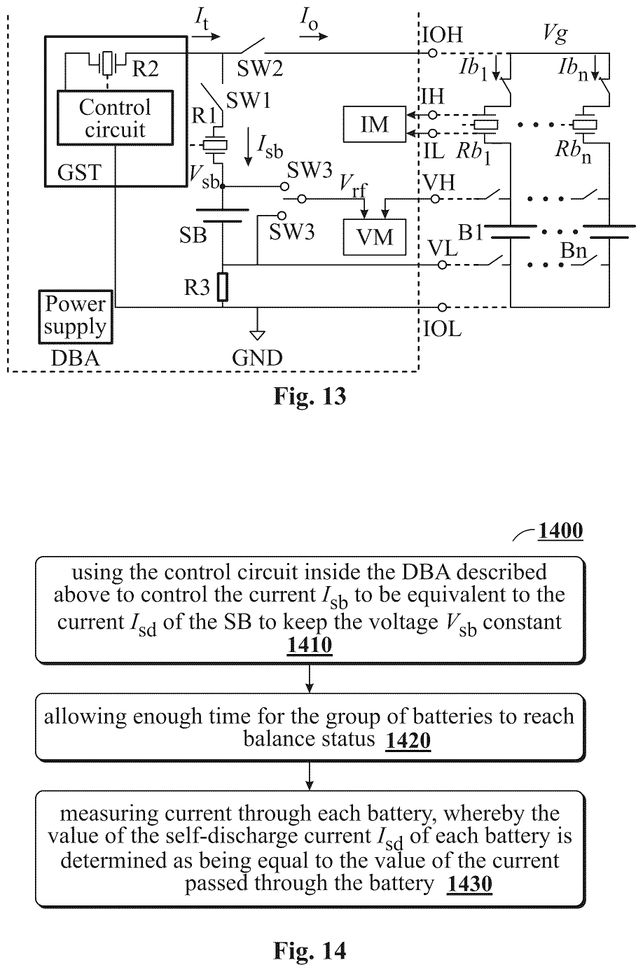

FIG. 13 is an illustrative circuit for measuring Isd of a group of batteries connected in parallel by applying constant current to the batteries with the DBA, according to the present disclosure. As shown in FIG. 13, a group of batteries connected in parallel can be connected to the DBA via the terminals (IOH) and (IOL). Besides, the group of batteries are further connected to the IM inside the DBA via terminals (IH) and (IL). In such examples, each of the IM and the VM has a plurality of channels for measuring multiple batteries simultaneously. That is, the current through each battery of the group of batteries and the voltage change due to the current can be measured by means of the IM and the VM, respectively.

With reference to FIG. 13, a galvanostatic method for measuring self-discharge current (Isd) of batteries connected in parallel is provided as follows. For example, small currents I1 and I2 from the GST can be applied to the batteries when SW2 is on. For one battery of the batteries connected in parallel, the current therethrough and the voltage change thereof can be measured by means of the IM and the VM, respectively. Then, Isd and dynamic capacitance (DNC) of the battery can be calculated by solving the two equations provided above. Thus, a galvanostatic method to obtain Isd and DNC of every battery in the group, as well as the SB, is provided.

FIG. 14 depicts another example process 1400 for measuring Isd by applying constant current to the battery, in accordance with examples of the disclosure. For example, some or all of the process 1400 may be performed by one or more components in the DBA shown in FIGS. 2-FIG. 8, as described herein.

At operation 1410, the process may include using the control circuit inside the DBA described above to control the current Isb to be equivalent to the current Isd of the SB to keep the voltage Vsb constant, wherein a group of batteries are connected in parallel to the DBA via the terminals (IOH) and (IOL). In some examples, the means includes the GST. Alternatively, the GST may control the current Isb using the feedback from the sensor R1. In such examples, the current Isd of the battery SB is predetermined. Alternatively, the current Isd of the battery SB can be determined using the galvanostatic method described above with reference to FIG. 11.

At operation 1420, the process may include allowing enough time for the group of batteries to reach a balanced status. In such examples, voltage of each battery under test will reach and remain constant at its OCV under that balanced status.

At operation 1430, the process may include measuring current through each battery, whereby the value of the self-discharge current Isd of each battery is determined as being equal to the value of the current passed through the battery. In some examples, current through one battery (denoted as battery#) of the batteries (denoted as Ib#) will reach the self-discharge current of the battery# (denoted as Isd#) when the batteries reach their balanced status. Thus, there is no need to measure voltage and dV/dt of each battery.

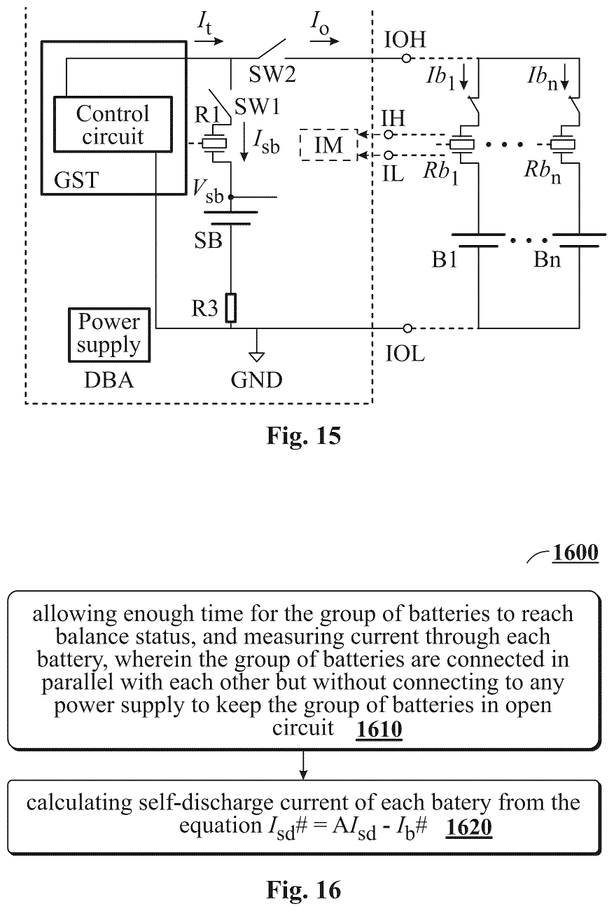

FIG. 15 is another illustrative circuit for measuring Isd by applying constant current to the battery with the DBA, according to the present disclosure. As shown in FIG. 15, a group of batteries in parallel can be connected to the DBA described above via the terminals (IOH) and (IOL).

In some examples, the DBA may further comprise an IM as discussed above. In such examples, the IM can measure current through each battery by means of a plurality of channels. It can be understood that the value of the current Isd of each battery is determined as equal to the value of the current through its corresponding battery with reference to the method illustrated in FIG. 14 with both SW1 and SW2 on.

FIG. 16 depicts another example process 1600 for measuring Isd of batteries in a group that are connected in parallel, in accordance with examples of the disclosure, which is called a passive method. For example, FIG. 15 provides an illustrative circuit for carrying out the passive method, where the batteries can be in open circuit when SW2 is left off.

At operation 1610, the process may include allowing enough time for the group of batteries to reach a balanced status, and measuring current through each battery, wherein the group of batteries are connected in parallel with each other, but without connecting to any power supply to keep the group of batteries in open circuit. In some examples, current through one battery of the batteries (battery#) can be denoted as Ib#. In some examples, balanced status may be considered to have been reached when the current through the battery or voltage change rate of the battery no longer varies or varies within a predetermined small range.

At operation 1620, the process may include calculating self-discharge current of each battery (denoted as Isd#) from the equation: Isd#=AIsd−Ib#. AIsd represents average self-discharge current of all batteries in the group. Ib# represents the current through the corresponding battery#. Assuming the difference of dynamic capacitance (DNC) of all batteries in the group can be ignored in calculation of self-discharge current and AIsd is known, self-discharge current of each battery can be calculated from the above equation. Thus, there is no need to measure voltage and dV/dt of each battery, assuming the DNC of batteries is known and the difference of DNC between batteries can be ignored. This method is especially useful in a finishing procedure in battery manufacturing.

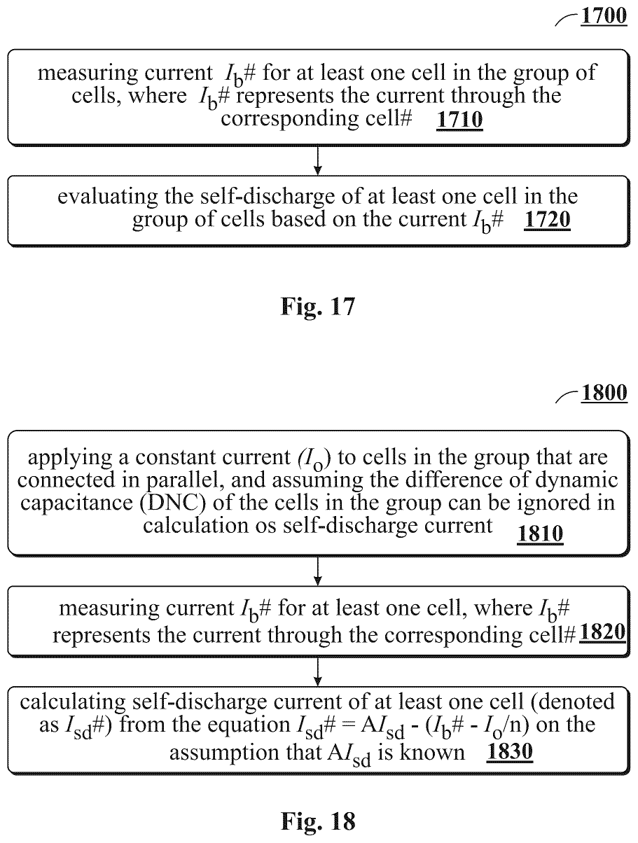

FIG. 17 depicts an illustrative block flow diagram for a process 1700 for measuring self-discharge of cells in the group under same voltage, according to the present disclosure. At operation 1710, the process may include measuring current Ib# for at least one cell in the group of cells, where Ib# represents the current through the corresponding cell#. In this embodiment, cells in the group are under same voltage. In some examples, the current Ib# is measured after allowing enough time for the group of cells to reach a balanced status. In some examples, current Ib# for at least one cell can be measured. In some examples, each current flowing through each cell# can be measured. In some examples, the cells in the group are connected in parallel with each other cell. At operation 1720, the process may include evaluating the self-discharge of at least one cell in the group of cells based on the current Ib#. In this embodiment, the Isd# can be reflected by the Ib# value, where cells in the group are under same voltage. In some examples, Ib# value may be used as a standard for cell quality judgment and/or cell classification.

FIG. 18 depicts another example process 1800 for measuring Isd of cells in a group that are connected in parallel, in accordance with examples of the disclosure. For example, FIG. 15 provides an illustrative circuit for carrying out the process 1800, where a current (denoted as I_{O}) is applied to cells connected in parallel with SW1 opened and SW2 closed.

At operation 1810, the process may include applying a constant current (I_{O}) to cells in a group that are connected in parallel, and assuming the difference of dynamic capacitance (DNC) of the cells can be ignored in calculation of self-discharge current. This means an average current I_{O} In is applied to each cell in the group, where n represents the number of cells in the group.

In some examples, the current (I_{O}) is applied using a galvanostat. In some examples, the current (I_{O}) is applied using the DBA described above. In some examples, the process may include applying a constant voltage to cells in a parallel group to make a current (I_{O}) flowing through the cell group. This potentiostat operation is equivalent to applying a current I_{O} to the cell group. In some examples, the constant voltage is applied using a potentiostat.

In some examples, the absolute value of I_{O} can be controlled to be equivalent to that of total self-discharge current (TIsd) of the cell group. In these examples, TIsd is assumed known. In some examples, TIsd can be obtained by statistics. In some examples, TIsd can be calculated as described below.

At operation 1820, the process may include measuring current Ib# for at least one cell, where Ib# represents the current through the corresponding cell#.

At operation 1830, the process may include calculating self-discharge current of at least one cell (denoted as Isd#) from the equation: Isd#=AIsd−(Ib#−IO In) on the assumption that AIsd is known, where AIsd represents average self-discharge current of the cells. In some examples, self-discharge current of each cell can be calculated from the above equation. In some examples, compared with the passive method described above, the current IO In may be included in Ib# under these circumstances. Thus, the equation Isd#=AIsd−(Ib#−IO In) can be derived from the equation Isd#=AIsd−Ib# described in the above operation 1620.

Thus, there is no need to measure voltage and dV/dt of each cell, assuming the DNC of cells is known and the difference of DNC between cells can be ignored. This method is especially useful in a finishing procedure in battery manufacturing for being able to identify a bad cell with high Isd value and hence to prevent a hazardous situation.

In some examples, since IO=−TIsd, and AIsd=TIsd In, for each cell# in the cell group, the equation: Isd#=AIsd−(Ib#−IO In) becomes Isd#=−Ib#, which means Isd# can be directly and precisely gotten by measuring Ib# by applying constant voltage to the cell group or applying I_{O} to the cell group, where I_{O}=−TIsd.

In some examples, such AIsd is determined as a ratio of total self-discharge current (TIsd) of the group of batteries to the number of the batteries in the group being tested. In such examples, the group of batteries can be regarded as an equivalent battery in calculation of total self-discharge current. For example, FIG. 13 provides an illustrative circuit for calculating the total self-discharge current. In such example, both SW1 and SW2 are left on. In some examples, the total self-discharge current can be determined with reference to the galvanostatic method described above. To be specific, the galvanostatic method can comprise the steps of: applying a first constant current (I1) and a second constant current (I2) to the group of batteries connected in parallel for a period of time (dt1) and for the same or a different period of time (dt2) respectively, wherein the currents I1 and I2 are low enough not to interrupt the electrochemical balance of the group of batteries being tested; measuring a first voltage change (dV1) and a second voltage change (dV2) of the group of batteries being tested over the periods of time dt1 and dt2, respectively; calculating a first voltage change rate (dV1/dt1) for the period of time dt1 at the current I1 and a second voltage change rate (dV2/dt2) for the period of time dt2 at the current I2; calculating total self-discharge current (TIsd) and total dynamic capacitance (TDNC) of the group of batteries being tested by solving two equations: (dV1/dt1)*TDNC=I1+TIsd, and (dV2/dt2)*TDNC=I2+TIsd. Thus, a galvanostatic method to obtain AIsd of the battery group is provided.

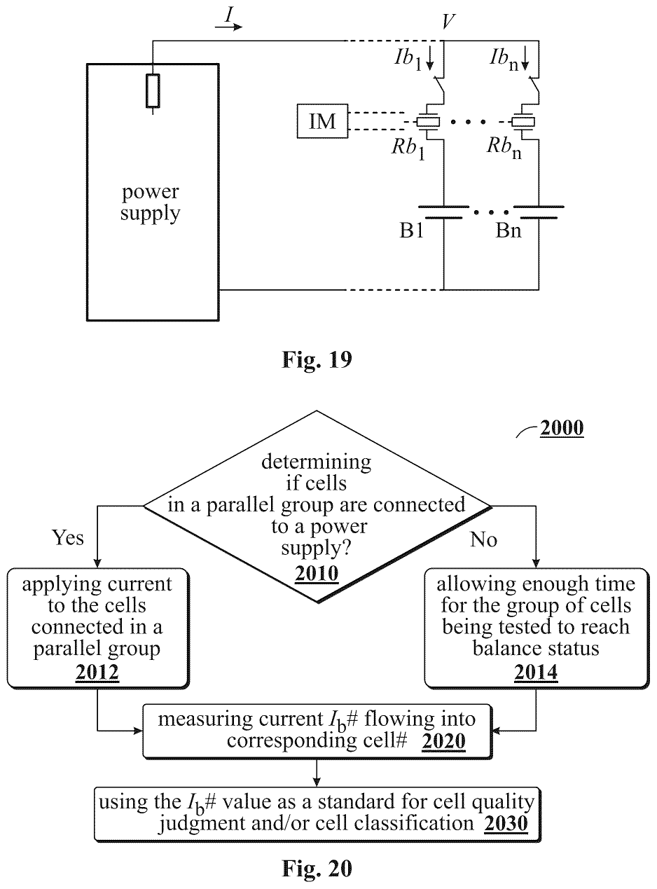

FIG. 19 is an illustrative circuit for using current of cells in a parallel group as a quality control method, according to the present disclosure.

As shown in FIG. 19, a group of cells (denoted as B1~Bn) in parallel can be connected to a power supply. For each cell in the group, a sensor may be connected with the cell# in series for measuring the current (Ib#) through the cell#. In some examples, the power supply may be a galvanostat. In some examples, the power supply may be a potentiostat. In some examples, the group of cells in parallel can be connected to the DBA described above via the terminals (IOH) and (IOL) as shown in FIG. 15 with both SW1 and SW2 on.

In some examples, the group of cells (denoted as B1~Bn) are connected in parallel with each other but without connecting to any power supply to keep the group of cells in open circuit. For example, the power supply shown in FIG. 19 is off. For example, the group of cells can be in open circuit as shown in FIG. 15 when SW2 is left off.

FIG. 20 depicts an example process 2000 for using current of cells in a parallel group as a quality control method, in accordance with examples of the disclosure.

At operation 2010, the process may include determining if cells in a parallel group are connected to a power supply.

If yes, at operation 2012, the process may include applying current to the cells connected in a parallel group.

If no, at operation 2014, the process may include allowing enough time for the group of cells being tested to reach balance status.

In this embodiment, the Ib# value measured directly can reflect differences among self-discharge current of cells connected in parallel. In some examples, current flowing into each cell can be measured.

At operation 2020, the process may include measuring current Ib# flowing into corresponding cell#.

At operation 2030, the process may include using the Ib# value as a standard for cell quality judgment and/or cell classification.

In this embodiment, the Isd# can be reflected by the Ib# value, because Ib#=AIsd−Isd# and average self-discharge current AIsd is approximately the same for each cell#. Thus, the Ib# value obtained by the above method can be used as the standard for cell quality judgment and/or cell classification in the same way as Isd#, especially in battery testing and production.

Generally, the larger the Isd#, the better the cell quality, wherein Isd # is negative. Accordingly, the smaller the Ib#, the better the cell quality. In some examples, if Ib# value is negative, it means that the corresponding cell# is charging at least one other cell, which implies the corresponding cell# usually has better quality than the at least one other cell being charged.

In some examples, the cells can be classified or sorted according to the consistency of the Ib# value or the Isd# value, especially in forming and testing batteries.

In some examples, the Isd# can be measured by the passive method for measuring self-discharge current (Isd) of cells in a group that are connected in parallel mentioned above.

In some examples, abnormal distributed current through cell (Ib#) of parallel cell group can be used as a criterion for battery safety judgment. In some examples, parallel cells tested in the same group may be prepared to be designed as one battery. In some examples, if an Ib# value is significantly larger than current through other cells or Ib# value is larger than a first preset safe current threshold, we can consider that there are certain safety risks associated with the corresponding cell#. Typically, an internal short circuit in cell# can cause an increase in the corresponding self-discharge current (Isd#). Considering the Isd# is difficult to measure quickly, this technology may diagnose cell's internal micro-shortage effectively in advance to prevent thermo-runaway and hence greatly improve safety protection level, especially in testing, formation and storage.

In some embodiments, the process may further include using abnormal distributed current through cell (Ib#) of the parallel group, as a criterion for cell safety judgment.

In some examples, current Ib# flowing into each cell# can be measured when charging the cell group. In some examples, potential risks can be diagnosed when a measured Ib# is significantly larger than current through other cells or the measured Ib# value is larger than a second preset safe current threshold. The principle of this method is similar to that of using current of cells in a parallel group at open circuit condition as a quality control method described above, differing only in whether or not a current is applied to the cell group.

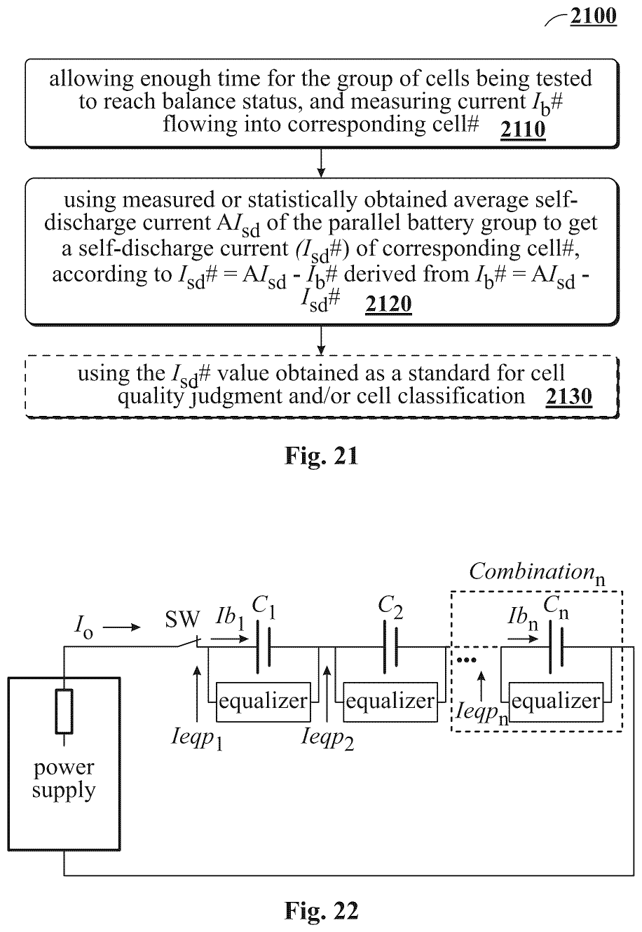

FIG. 21 is yet another illustrative block flow diagram for a process 2100 for measuring Ib# of cells in a parallel group, according to the present disclosure. For example, FIG. 15 provides an illustrative circuit for carrying out the method, where the cells can be in open circuit when SW2 is left off.

At operation 2110, the process may include allowing enough time for the group of cells being tested to reach balance status, and measuring current Ib# flowing into corresponding cell#, where the group of cells are connected in parallel with each other but without connecting to any power supply to keep the group of cells in open circuit.

In this embodiment, descriptions of operation 2110 may be consistent with that of operation 2014 and operation 1710.

At operation 2120, the process may include using measured or statistically obtained average self-discharge current AIsd of the parallel battery group to get a self-discharge current (Isd#) of corresponding cell#, according to Isd#=AIsd−Ib# derived from Ib#=AIsd−Isd#. In some examples, AIsd can be calculated as described above. In some examples, self-discharge current of each cell can be calculated.

Alternatively, at operation 2130, the process may further include using the Isd# value obtained as a standard for cell quality judgment and/or cell classification. Thus, this method provides another standard for cell quality judgment and/or cell classification, which can use the value of Isd# directly.

FIG. 22 is an illustrative circuit for a method for measuring self-discharge current (Isd) of cells in a group that are connected in series with an equalizer for each cell, according to the present disclosure.

As shown in FIG. 22, a group of cells (denoted as C1~Cn) are connected in series with an equalizer for each cell. In this embodiment, each equalizer is used to keep corresponding cell under controllable voltage. In some examples, all cells connected in a serial group can be under same voltage all the time with the equalizers on. This is similar to paralleling cells where cells are under same voltage.

In this embodiment, each equalizer may have a fully bidirectional charge/discharge channel with at least two current ranges, and at least one current range is low enough to be capable of measuring self-discharge current. This means the equalizer here is not a traditional equalizer. In some examples, a battery management system (BMS) with current ranges matching requirements above can act as the equalizer. In some examples, the equalizer may be called equalizer plus (EQP). An EQP may include a DBA described above, plus a fully bidirectional charge/discharge channel between the terminals (IOH) and (IOL) for measuring current. The channel has at least two current ranges, and at least one current range is low enough to be capable of measuring self-discharge current.

In some embodiments, current (denoted as Ieqp#) flowing through equalizer# connected to corresponding cell# can be measured when there are fairly good balance status among cells in the group. In some examples, when Ieqp# is nearly stable, it can be considered to reach balanced status. In some examples, each current flowing through each equalizer# connected to corresponding cell# can be measured.

In some embodiments, current (denoted as Ieqp#) flowing through equalizer# connected to corresponding cell# can be calculated according to equation: Ieqp#=Ib#−I_{O}, where I_{O} represents the current flowing through combination# of the cell# and corresponding equalizer#.

In this embodiment, self-discharge current of at least one cell# (denoted as Isd#) can be calculated from the equation: Isd#=−Ieqp#. In some examples, self-discharge current of each cell# can be calculated. This is based on the principle that all cells connected in the serial group are under same voltage.

In some examples, a power supply can be connected to the cell group with SW closed to apply a current (I_{O}) to the group of cells. In these examples, I_{O} is low enough not to interrupt the electrochemical balance of the cells. In some examples, the group of cells are at open circuit condition with SW opened, i.e. I_{O}=0.

This invention can be applied to battery testing and formation, as well as in a battery pack such as for electrical vehicles and battery energy storage systems, where it is impossible to measure current for each cell via a transducer or a sensor. Thus, this method is especially useful in a battery pack for being able to identify a bad cell with high Isd value and hence to prevent a hazardous situation.

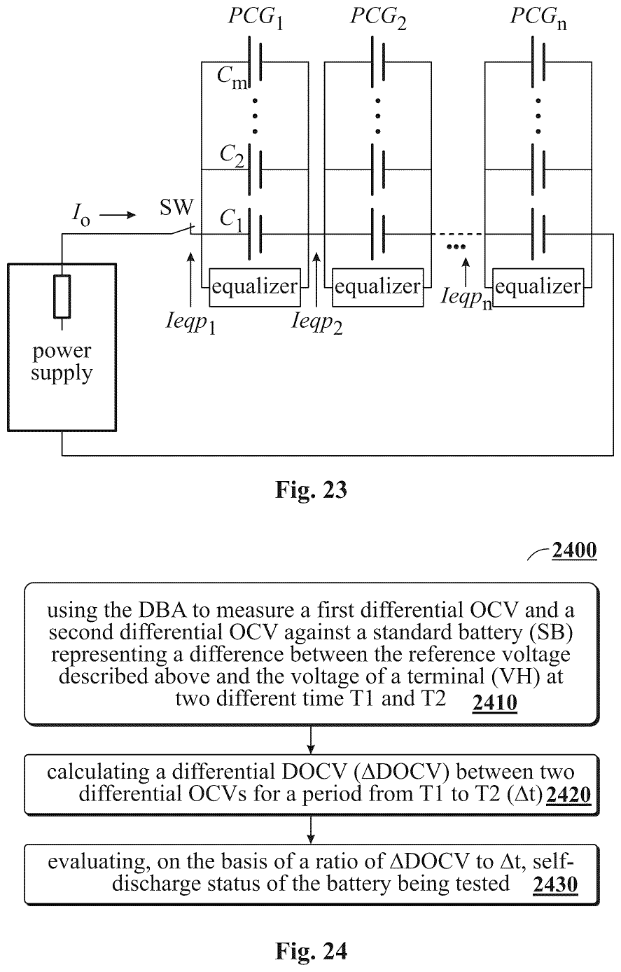

FIG. 23 is an illustrative circuit for a method for measuring self-discharge current (Isd) of parallel cell groups (PCGs) that are connected in series with an equalizer for each PCG, according to the present disclosure.

As shown in FIG. 23, a group of PCGs (denoted as PCG1~PCGn) are connected in series with an equalizer for each PCG. For each PCG, a group of cells (denoted as C1~Cm) are connected in parallel and each cell of one PCG has very similar specifications and characters. The number of cells in each PCG is preferably the same.

In this embodiment, each equalizer is used to keep corresponding PCG under controllable voltage. In some examples, all PCGs connected in a serial group can be under same voltage all the time with the equalizers on. This is similar to paralleling PCGs where PCGs are under same voltage. Each equalizer may have a fully bidirectional charge/discharge channel with at least two current ranges, and at least one current range is low enough to be capable of measuring self-discharge current. The descriptions of the equalizer here can be consistent with the previous one.

In this embodiment, current (denoted as Ieqp#) flowing through equalizer# connected to corresponding PCG# can be measured when there is fairly good balance status among PCGs in the group. In some examples, when Ieqp# is nearly stable, it can be considered to reach balanced status. In some examples, current Ieqp# for at least one equalizer can be measured. In some examples, each current flowing through each equalizer# connected to corresponding PCG# can be measured. Thereby, self-discharge current of at least one PCG# (denoted as Isd#) can be calculated from the equation: Isd#=−Ieqp#.

In some examples, a power supply can be connected to the PCG group with SW closed to apply a current (I_{O}) to the PCGs. In these examples, I_{O} is low enough not to interrupt the electrochemical balance of the cells. In some examples, the group of PCGs are at open circuit condition with SW opened, i.e. I_{O}=0.

In this embodiment, all cells in parallel of one PCG can be regarded as an equivalent cell. The principle of this method is similar to the method for measuring self-discharge current (Isd) of cells in a group that are connected in series with an equalizer for each cell described above, differing only in replacing a cell with a PCG.

This invention can be applied in battery packs such as for electrical vehicles and battery energy storage systems, where it is impossible to measure current for each cell via a transducer or a sensor. Thus, this method is especially useful in battery packs for measuring SDC of a parallel cell group efficiently.

FIG. 24 depicts an example process 2400 for evaluating self-discharge of a battery by means of a DBA with a VM, in accordance with examples of the disclosure. For example, some or all of the process 2400 may be performed by one or more components in the DBA shown in FIGS. 4-FIG. 8, as described herein.

At operation 2410, the process may include using the DBA described above to measure a first differential OCV (denoted as DOCV1) and a second differential OCV (denoted as DOCV2) against the standard battery (SB) representing a difference between the reference voltage described above and the voltage of a terminal (VH) at two different times T1 and T2, wherein a battery being tested is connected to the DBA with a VM described above via terminals (VH) and (VL). In some examples, the DBA further comprises a first current sensor connected to the SB in series for measuring the current through the SB and providing feedback to control an output current from the control circuit. In such examples, the current through the SB is controlled to be equal to self-discharge current of the SB, whereby the voltage of the SB is kept constant at its open-circuit voltage (OCV). For example, an illustrative circuit for carrying out the method can be referred to FIG. 8 with SW1 on. In some examples, DOCV1=V1−Vrf and DOCV2=V2−Vrf are satisfied, where V1 and V2 represent the voltage of the terminal at times T1 and T2, respectively. In some examples, each of T1 and T2 is less than 24 hours.

At operation 2420, the process may include calculating a differential DOCV (ΔDOCV) between two differential OCVs for a period from T1 to T2 (Δt). In such examples, ΔDOCV=DOCV2−DOCV1 and Δt=T2−T1.

At operation 2430, the process may include evaluating, on the basis of a ratio of ΔDOCV to Δt, self-discharge status of the battery being tested. In some examples, a K value representing the ratio of ΔDOCV to Δt of a battery can be calculated to evaluate self-discharge status of the battery under test. This method for measuring differential OCV can be particularly useful in making batteries

In some examples, a battery being tested includes a group of batteries. Each of the group of batteries can connect or disconnect to the VM via a switch. In such examples, the process may further include sorting the group of batteries according to the self-discharge status. In such examples, the group of batteries can be sorted according to their values of self-discharge parameters. These parameters may include, but not be limited to, at least one of the following: OCV, SD representing a differential DOCV (ΔDOCV) between two differential OCVs for a period of time, and the K value mentioned above. In some examples, these parameters may further include, but not be limited to, at least one of Isd and SDR. In this way, batteries having reasonably consistent values for the parameters can be sorted into one group. Compared with other methods for grading and sorting batteries that include modeling, algorithms and electrochemical analysis, this method provided in the present disclosure is much easier, thereby saving or reducing storage time and improving the battery manufacturing process.

In some examples, the process may further include calculating self-discharge current (Isd) of one or more batteries in the group on the basis of known dynamic capacitance (DNC) value of one or more batteries in the group or average DNC value of the group of batteries. In such examples, self-discharge current of each battery is calculated from the equation: Isd#=ΔQ/Δt=DNC (or ADNC)*ΔDOCV/Δt, where Isd# represents the self-discharge current of the target battery#, ΔQ represents change of electricity, where i=ΔQ/Δt, and ADNC represents average DNC value of all batteries in the group.

In some examples, ADNC can be calculated from obtained historical DNCs. In some examples, an ADNC value of the group of batteries can be determined as a ratio of total DNC (TDNC) of all batteries in the group to the number of the batteries in the group being tested. Alternatively, the TDNC can be determined with reference to the galvanostatic method described above regarding the group of batteries as an equivalent battery by solving two equations: (dV1/dt1)*TDNC=I1+TIsd, and (dV2/dt2)*TDNC=I2+TIsd.

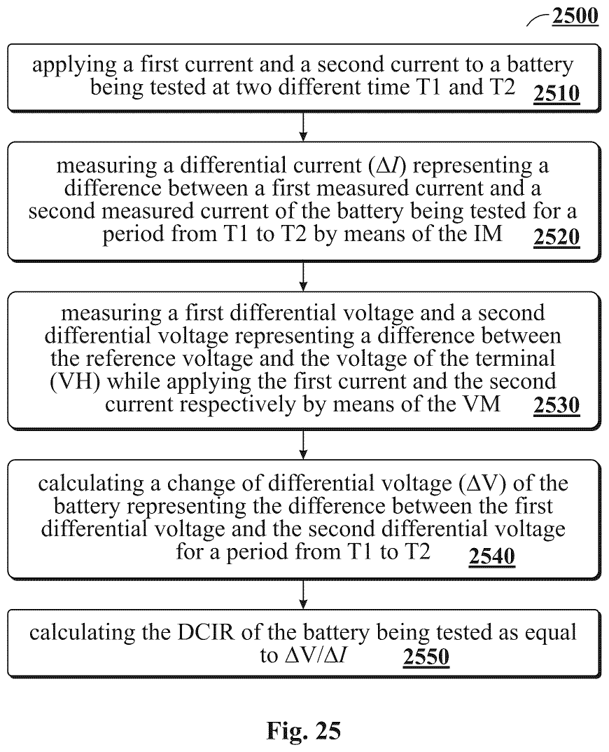

FIG. 25 depicts an example process 2500 for measuring direct current internal resistance of a battery by means of a DBA, in accordance with examples of the disclosure. For example, FIG. 13 provides an illustrative circuit for carrying out this method with both SW1 and SW2 on.

At operation 2510, the process may include applying a first current and a second current to a battery being tested at two different times T1 and T2, wherein a battery being tested is connected to the DBA described above via terminals (VH) and (VL). The DBA further comprises two terminals (IH) and (IL) connected to a circuit block for current measurement (IM), wherein a sensor is connected between terminals (IH) and (IL) and connected with the battery in series for measuring the current through the battery. In some examples, the first current and the second current are low enough not to interrupt the electrochemical system of the battery. In some examples, the IM may have a plurality of channels for measuring current through each battery in a group connected thereto.

At operation 2520, the process may include measuring a differential current (ΔI) representing a difference between a first measured current and a second measured current of the battery being tested for a period from T1 to T2 by means of the IM. In some examples, for one battery of a group of batteries (denoted as battery#), a differential current is determined by the equation: ΔI b#=Ib#2−Ib#1. Ib#1 and Ib#2 represent the first measured current and the second measured current through battery# using the IM, respectively.

At operation 2530, the process may include measuring a first differential voltage and a second differential voltage representing a difference between the reference voltage and the voltage of the terminal (VH) while applying the first current and the second current respectively by means of the VM. In some examples, for one battery of the batteries (denoted as battery#), a first differential voltage is determined by the equation: Vb#1=V#1−Vrf. V#1 represents the voltage of the terminal (VH) of battery# while applying the first current. And a second differential voltage is determined by the equation: Vb#2=V#2−Vrf. V#2 represents the voltage of the terminal (VH) of battery# while applying the second current.

At operation 2540, the process may include calculating a change of differential voltage (ΔV) of the battery representing the difference between the first differential voltage and the second differential voltage for a period from T1 to T2. In some examples, for one battery of the batteries (denoted as battery#), the change of differential voltage (ΔV) of the battery being tested for a period from T1 to T2 is determined by the equation: ΔV#=Vb#2−Vb#1.

At operation 2550, the process may include calculating the DCIR of the battery being tested as equal to ΔV/ΔI. In some examples, for one battery of the group of batteries (denoted as battery#), the DCIR of the battery being tested is determined by the equation: DCIR #=ΔV#/ΔI#. Similarly, the equivalent resistance of a group of batteries under test can be calculated with reference to the above method regarding the group of batteries as an equivalent battery. This method usually can be applied to battery testing, especially in battery formation.

An auto analyzer for evaluating batteries is provided in this disclosure. In some examples, an auto analyzer for evaluating batteries may comprise a power supply, one or more processors and one or more storage media storing instructions executable by the one or more processors, wherein the instructions, when executed, cause the auto analyzer to perform operations according to any one of the following: a method for measuring differential voltage, a galvanostatic method for measuring self-discharge current of a battery, a galvanostatic method for measuring self-discharge current of a battery using a differential analyzer described above, a passive method for measuring self-discharge current of batteries in a group that are connected in parallel, a method for evaluating self-discharge of a battery and a method for measuring direct current internal resistance of a battery. Detailed descriptions of these methods have been discussed above with reference to FIG. 8 to FIG. 25.

In some examples, the processor(s) may be any suitable processor capable of executing instructions to process data and perform operations as described herein. By way of example and not limitation, the processor(s) may include one or more central processing units (CPUs), graphics processing units (GPUs), or any other device or portion of a device that processes electronic data to transform that electronic data into other electronic data that can be stored in registers and/or memory. In some examples, the processor(s) may include a circuit assembly, such as integrated circuits (e.g, ASICs, etc.), gate arrays (e.g, FPGAs, etc.), and other hardware devices in so far as they are configured to implement encoded instructions.

In some examples, the storage media may include non-transitory computer-readable media, such as a memory. In such examples, the memory may store an operating system and one or more software applications, instructions, programs, and/or data to implement the methods described herein and the functions attributed to the various systems. In various implementations, the memory can be implemented using any suitable memory technology, such as static random access memory (SRAM), synchronous dynamic RAM (SDRAM), nonvolatile/flash-type memory, or any other type of memory capable of storing information.

In some instances, the memory may include at least a working memory and a storage memory. For example, the working memory may be a high-speed memory of limited capacity (e.g, cache memory) that is used for storing data to be operated on by the processor(s). In some instances, the memory may include a storage memory that may be a lower-speed memory of relatively large capacity that is used for long-term storage of data. In some cases, the processor(s) may not operate directly on data that is stored in the storage memory, and data may need to be loaded into a working memory for performing operations based on the data, as discussed herein.

In some examples, the auto analyzer may be integrated into a DBA described above. In such cases, the DBA with the auto analyzer is capable of testing various parameters of a battery automatically.

It can be understood that the architectures, systems, and individual elements described herein can include many other logical, programmatic, and physical components, of which those shown in the accompanying figures are merely examples that are related to the discussion herein.

### FURTHER EMBODIMENTS OF THE INVENTION

For a battery at a fully balanced status, a very small current at the level of leakage current of the battery will cause a linear voltage change against time within very small voltage range such as 10's of microvolts to a few millivolts. In this invention, a battery at its fully balanced status is considered as behaving like a supercapacitor within a small voltage range at a very small current. Supercapacitor behavior follows (dV/dt)*C=I+LC, where LC is leakage current and C is capacitance and I is the current applied to the capacitor. For a supercapacitor, C is a constant value and does not change with SOC (State of Charge), while leakage current LC will change along with SOC of supercapacitor. When voltage change rate dV/dt is measured with constant current I, LC can be calculated with known C value as LC=(dV/dt)*C−I. Using a supercapacitor to model a battery, a battery will have dynamic LC and dynamic C at certain SOC and follow (dV/dt)*C=I+LC, where both LC and C will change with different SOC. If two different currents I1 and I2 are applied at a same SOC and one measures (dV/dt)1 and (dV/dt)2 correspondingly, assuming both LC and C are same for the two currents, one can get LC and C values of the battery by solving two equations (dV/dt)1*C=I1+LC and (dV/dt)2*C=I2+LC. When the battery is fully balanced and this SOC and current I1 and 12 would not interrupt significantly the electrochemical balance of the battery, the dynamic LC calculated accordingly can be considered as leakage current at this SOC. When I1 and I2 is multiple times larger than LC, dV/dt is larger and needs less time to measure and/or needs less voltage precision from a voltmeter. Only a few hours is enough to measure LC of a battery at 95%~100% SOC.

Because current control is much easier than voltage control in very low current level and because a battery is very sensitive to even very small voltage noise/ripple, this method requires much simpler and low cost testing systems and needs much shorter time to get reliable results as compared to methods using voltage control. A regular battery testing system and battery formation system with high enough measurement accuracy/precision can be used for this method, instead of using special equipment, which could be very expensive and not precise enough.

If dynamic capacitance (DNC) of battery is known within a certain accuracy, dynamic LC (DNLC) can be calculated directly from (dV/dt)*C=I+LC, where dV/dt, C and I are known or measured.

When a number (N) of batteries with very similar characters are connected in parallel we can assume that the parallel group of batteries has a certain average dynamic capacitance ADNC=sum(DNC(1):DNC(N))/N and certain average dynamic leakage current ADNLC=sum(DNLC(1):DNLC(N))/N. When the paralleled battery group reaches an electrochemical balanced status, one should have DNLC(n)=ADNLC−I(n)+Ig/N, where I(n) is the current flow into the battery n and Ig is the total current flow into the parallel battery group. If we can assume that batteries with same chemical and mechanical structure and same specifications have fairly constant ADNC and ADNLC, which may be true in a massive battery testing and formation process, where battery cells are connected in parallel, one can directly measure each battery's leakage current by measuring current flow into each battery while the battery group is under balanced status and there is zero or very small external current flow Ig through the parallel group by DNLC(n)=ADNLC−I(n)+Ig/N. This process involves only current measurement under open circuit or very small current to the battery group and can be done instantly when the battery group reaches balancing status without need of a long time for voltage control/change and measurement. This invention will significantly lower the time and equipment needed for battery manufacturing.

Even if one does not have an exact value of ADNLC and DNLC(n), one still can compare DNLC of each battery in the parallel group by the value of I(n) once the parallel battery group is in balanced status. The effect of comparing I(n), or ALC(n)=LC(n)−ALC, instantly would be similar to comparing voltage drop AV(n) over a long period of time.

Additional embodiments of the invention include the following: a mechanism that uses a dynamic supercapacitor with dynamic capacitance and dynamic leakage current to model a battery during leakage current measurement; using the above model, applying two different currents, which are low enough not to interrupt the electrochemical balance of the battery but high enough to accelerate the test, to get two equation (dV/dt)1*C=I1+LC and (dV/dt)2*C=I2+LC. LC and C value of the battery can be solved from these 2 equations; using current control instead voltage control to batteries for leakage current measurement; connect a number of batteries in parallel without applying any current to the group (open circuit), measure current through each battery to get the difference of leakage current from average leakage current ALC(n)=LC(n)−ALC. LC(n)=ALC(n)−Ib(n); by solving the two equation (dVg/dt)1*ADNC=ADNLC and (dVg/dt)2*ADNC=Ig+ADNLC to get ADNC and ADNLC, assuming ADNC=sum(LC1:LCn)/n and ADNC=sum(C1:Cn)/n; by applying Ig=−N*ALC to the parallel battery group and check if dVg/dt is close to 0 (in μV level), to check if ALC is the right value, and one can calculate the actual ALC; and using only one current source to or even without a current source to measure multiple cells' leakage current simultaneously.

### Embodiments Disclosed in Application No. PCT/US2023/081285

The apparatus, equipment and methods described herein builds on and includes description from the present inventor's International Patent Application No. PCT/US2023/081285 titled “Analyzer and Method for Determining Self-Discharge of Batteries,” which was published as Publication No. WO 2024/129355. The disclosure in the present inventor's International Patent Application No. PCT/US2023/081285 is ALSO included in the inventor's U.S. Provisional Patent Application Ser. No. 63/560,645 filed on 2 Mar. 2024 titled “Measuring Self Discharge of Batteries,” which is claimed as a priority document.

The following is a brief summary of the disclosure in the present inventor's International Patent Application No. PCT/US2023/081285. A differential battery analyzer (DBA) for testing a battery includes a control circuit configured to apply a controllable current to a normal battery as a standard battery (SB) inside the DBA, wherein the current through the SB (Isb) is controlled to be equal to its self-discharge current, whereby a voltage of the SB is kept constant at its open-circuit voltage (OCV); and two terminals (IOH) and (IOL) for connecting a battery under test therebetween, wherein the terminal (IOH) is connected to an end of a branch where the SB is located, and the voltage between the terminal (IOH) and the terminal (IOL) is kept at a constant value approximately equal to the voltage of the SB within a desired precision, and the terminal (IOL) is connected to the other end of the branch. The normal battery preferably includes a secondary rechargeable battery, which preferably has the same type as the battery under test. The DBA preferably further comprises another two terminals (IH) and (IL) connected to a circuit block for current measurement (IM).

The DBA preferably further comprises a first current sensor connected to the SB in series for measuring the current through the SB and providing feedback to control an output current (It) from the control circuit. The DBA more preferably further comprises a second current sensor for measuring an output current from the control circuit and providing feedback to control the output current, preferably wherein the current flowing to the terminal (IOH) (I_{O}) is following to maintain the potential of the terminal (IOH) when a battery is connected to the DBA via the terminals (IOH) and (IOL), wherein It=I_{O}+Isb.

The DBA preferably further comprises another two terminals (VH) and (VL) and a circuit block for voltage measurement (VM) for measuring differential voltage between a reference voltage and the voltage of the battery under test which is connected to the DBA via the terminals (VH) and (VL), wherein the reference voltage is determined on the basis of the voltage of the SB. The reference voltage is preferably selected as one of a plurality of reference voltages within a range not greater than a value of the voltage of the SB. This DBA preferably further comprises a plurality of resistors connected serially with each other and in parallel with the branch where the SB is located, wherein each resistor has its respective reference voltage output terminal which is selected via a multiplexer connected to the VM, whereby the voltage of the SB is divided into a plurality of reference voltages.

Regarding the current flowing to the terminal (IOH) (I_{O}) following to maintain the potential of the terminal (IOH) when a battery is connected to the DBA via the terminals (IOH) and (IOL)11, preferably the control circuit includes a galvanostat, and the DBA preferably further includes a second current sensor, two terminals (VH) and (VL), another two terminals (IH) and (IL) connected to a circuit block for current measurement (IM), a circuit block for voltage measurement (VM), a first switch connected to the first sensor serially, a second switch located to connect or disconnect the current flowing to the terminal (IOH), a grounding resistor connected between the SB and the terminal (IOL), and a plurality of resistors connected serially with each other and in parallel with the branch where the SB is located, wherein each resistor has its respective reference voltage output terminal which is selected via a multiplexer connected to the VM, whereby the voltage of the SB is divided into a plurality of reference voltages, wherein the second sensor is configured to measure an output current from the galvanostat and providing feedback to control it, wherein the VM is configured to measure differential voltage between a reference voltage and the voltage of the battery under test which is connected to the DBA via the terminals (VH) and (VL), and wherein the reference voltage is determined on the basis of the voltage of the SB.

A method has been disclosed for measuring differential voltage using the DBA that includes the two terminals (VH) and (VL) and the and circuit block for voltage measurement (VM) for measuring differential voltage between a reference voltage and the voltage of the battery under test which is connected to the DBA via the terminals (VH) and (VL) and measuring a differential voltage representing a difference between the reference voltage and the voltage of the terminal (VH) by means of the VM, wherein a battery under test is connected to the terminals (VH) and (VL). The battery under test preferably includes a group of batteries connected in parallel.

A galvanostatic method for measuring self-discharge current (Isd) of a battery has been disclosed that comprises the steps of: applying a first constant current (I1) and a second constant current (I2) to a battery being tested for a period of time (dt1) and for the same or a different period of time (dt2) respectively, wherein the currents I1 and I2 are low enough not to interrupt the electrochemical balance of the battery being tested; measuring a first voltage change (dV1) and a second voltage change (dV2) of the battery being tested over the periods of time dt1 and dt2, respectively; calculating a first voltage change rate (dV1/dt1) for the period of time dt1 at the current I1 and a second voltage change rate (dV2/dt2) for the period of time dt2 at the current I2; calculating Isd and dynamic capacitance (DNC) of the battery being tested by solving equations (1) and (2), wherein equation (1) is (dV1/dt1)*DNC=I1+Isd, and equation (2) is (dV2/dt2)*DNC=I2+Isd. The battery being tested preferably includes a group of batteries connected in parallel.

The DBA described above can be used to apply a first constant current (I1) and a second constant current (I2) to a battery being tested for a period of time (dt1) and for the same or a different period of time (dt2), respectively, with the control circuit inside the DBA, wherein the battery being tested is connected to the DBA via the terminals (IOH) and (IOL), and the currents I1 and I2 are low enough not to interrupt the electrochemical balance of the battery being tested; measure a first voltage change (dV1) and a second voltage change (dV2) of the battery being tested over the periods of time dt1 and dt2, respectively; calculate a first voltage change rate (dV1/dt1) for the period of time dt1 at the current I1 and a second voltage change rate (dV2/dt2) for the period of time dt2 at the current I2; calculate Isd and dynamic capacitance (DNC) of the battery being tested by solving equations (1) and (2) in which equation (1) is (dV1/dt1)*DNC=I1+Isd, and equation (2) is (dV2/dt2)*DNC=I2+Isd.

The DBA used preferably includes the two terminals (VH) and (VL) and a circuit block for voltage measurement (VM) for measuring differential voltage between a reference voltage and the voltage of the battery being tested, wherein the reference voltage is determined on the basis of the voltage of the SB, and wherein the battery being tested is further connected to the DBA via the terminals (VH) and (VL), whereby the first voltage change and the second voltage change are measured by means of the VM. The battery being tested is preferably a group of batteries connected in parallel, wherein the group of batteries is further connected to a circuit block for current measurement (IM) inside the DBA via terminals (IH) and (IL), and wherein each of the IM and the VM has a plurality of channels and each of the channels is configured to measure current or voltage of a battery.

The DBA described a few paragraphs above that has the two terminals (IOH) and (IOL) can be used to measure self-discharge current of a group of batteries by using the control circuit inside the DBA to control the current through the SB to be equivalent to the current Isd thereof to keep the voltage of the SB constant, wherein the group of batteries are connected in parallel to the DBA via the terminals (IOH) and (IOL); allowing enough time for the group of batteries to reach a balanced status; and measuring current through each battery, whereby the value of the self-discharge current Isd of each battery is determined as being equal to the value of the current passed through the battery. The current Isd of the battery SB is preferably determined using the galvanostatic method described a few paragraphs above. The current through each battery is preferably measured by means of a circuit block for current measurement (IM) inside the DBA, and the DBA preferably includes two terminals (IH) and (IL) connected to the IM, wherein the IM has a plurality of channels and each of the channels is configured to measure current of a battery.

A passive method for measuring self-discharge current (Isd) of batteries in a group that are connected in parallel has been disclosed that includes the steps of allowing enough time for a group of batteries being tested to reach balance status, and measuring current through each battery, wherein the group of batteries are connected in parallel with each other but without connecting to any power supply to keep the group of batteries in open circuit; and calculating self-discharge current of each battery (Isd#) from the equation: Isd#=AIsd−Ib# on the assumption that a difference of dynamic capacitance (DNC) of all batteries in the group can be ignored in calculation of self-discharge current and AIsd is known, wherein AIsd represents average self-discharge current of the group of batteries, and Ib# represents the current through the corresponding battery#. The average self-discharge current of the group of batteries is preferably determined as a ratio of total self-discharge current of the group of batteries to a number of the batteries in the group being tested, wherein the group of batteries is regarded as an equivalent battery in calculation of total self-discharge current, wherein the total self-discharge current is determined using a galvanostatic method.

The galvanostatic method preferably includes the steps of applying a first constant current (I1) and a second constant current (I2) to the group of batteries connected in parallel for a period of time (dt1) and for the same or a different period of time (dt2) respectively, wherein the currents I1 and I2 are low enough not to interrupt the electrochemical balance of the group of batteries; measuring a first voltage change (dV1) and a second voltage change (dV2) of the group of batteries over the periods of time dt1 and dt2, respectively; calculating a first voltage change rate (dV1/dt1) for the period of time dt1 at the current I1 and a second voltage change rate (dV2/dt2) for the period of time dt2 at the current I2; calculating total self-discharge current (TIsd) and total dynamic capacitance (TDNC) of the group of batteries being tested by solving equations (1) and (2), wherein equation (1) is (dV1/dt1)*TDNC=I1+TIsd, and equation (2) is (dV2/dt2)*TDNC=I2+TIsd.

A method has been disclosed for evaluating self-discharge of a battery using the DBA described a few paragraphs above that includes the two terminals (VH) and (VL) and a circuit block for voltage measurement (VM) to measure a first differential OCV (DOCV1) and a second differential OCV (DOCV2) against the standard battery (SB) representing a difference between the reference voltage and the voltage of the terminal (VH) at two different times T1 and T2, wherein the battery being tested is connected to the terminals (VH) and (VL), wherein the DBA further comprises a first current sensor connected to the SB in series for measuring the current through the SB and providing feedback to control an output current from the control circuit, and wherein the current through the SB is controlled to be equal to self-discharge current of the SB, whereby the voltage of the SB is kept constant at its open-circuit voltage (OCV); calculating a differential DOCV (ΔDOCV) between two differential OCVs for a period from T1 to T2 (Δt); and evaluating, on the basis of a ratio of ΔDOCV to Δt, the self-discharge status of the battery being tested. The battery being tested preferably includes a group of batteries, and the method preferably further comprising sorting the group of batteries according to the self-discharge status. The method preferably further comprises calculating self-discharge current (Isd) of one or more batteries in the group on the basis of known dynamic capacitance (DNC) value of one or more batteries in the group or average DNC value of the group of batteries. The average DNC value of the group of batteries is preferably determined as a ratio of total DNC (TDNC) of the group of batteries to a number of the batteries in the group being tested, wherein the group of batteries is regarded as an equivalent battery in calculation of TDNC, wherein the DNC value of one or more batteries in the group or TDNC of the group of batteries is determined using a galvanostatic method.

The galvanostatic method preferably comprises the steps of applying a first constant current (I1) and a second constant current (I2) to a battery in the group or the group of batteries being tested for a period of time (dt1) and for the same or a different period of time (dt2), respectively, wherein the currents I1 and I2 are low enough not to interrupt the electrochemical balance of the battery or the group of batteries; measuring a first voltage change (dV1) and a second voltage change (dV2) of the battery or the group of batteries over the periods of time dt1 and dt2 respectively; calculating a first voltage change rate (dV1/dt1) for the period of time dt1 at the current I1 and a second voltage change rate (dV2/dt2) for the period of time dt2 at the current I2; calculating Isd and dynamic capacitance (DNC) of the battery being tested by solving equations (1) and (2), wherein equation (1) is (dV1/dt1)*DNC=I1+Isd, and equation (2) is (dV2/dt2)*DNC=I2+Isd, or calculating total self-discharge current TIsd and total dynamic capacitance (TDNC) of the group of batteries being tested by solving equations (3) and (4), wherein equation (3) is (dV1/dt1)*TDNC=I1+TIsd, and equation (4) is (dV2/dt2)*TDNC=I2+TIsd.

A method for measuring direct current internal resistance (DCIR) of a battery includes the steps of: applying a first current and a second current to a battery being tested at two different times T1 and T2, wherein a battery being tested is connected to a DBA described above via terminals (VH) and (VL), wherein the DBA further includes two terminals (IH) and (IL) connected to a circuit block for current measurement (IM), wherein a sensor is connected between terminals (IH) and (IL) and connected with the battery in series for measuring the current through the battery; measuring a differential current (ΔI) representing a difference between a first measured current and a second measured current of the battery for a period from T1 to T2 by means of the IM; measuring a first differential voltage and a second differential voltage representing a difference between the reference voltage and the voltage of the terminal (VH) while applying the first current and the second current respectively by means of the VM; calculating a change of differential voltage (ΔV) of the battery representing the difference between the first differential voltage and the second differential voltage for a period from T1 to T2; calculating the DCIR of the battery being tested as equal to ΔV/ΔI.

An auto analyzer has been disclosed for evaluating batteries that includes a power supply; one or more processors; and one or more storage media storing instructions executable by the one or more processors, wherein the instructions, when executed, cause the auto analyzer to perform operations for executing the steps in the methods described above.

A battery testing apparatus has been disclosed that includes a normal battery operating as a standard battery (SB); a constant current source configured to apply a controllable current through the normal battery (Isb) that is equal to its self-discharge current, whereby a voltage of the normal battery is held constant at its open-circuit voltage (OCV); and a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision. The battery testing apparatus preferably further comprising a first current sensor configured to measure the current through the SB and to provide feedback to control an output current (It) from the constant current source. The normal battery preferably comprises a secondary rechargeable battery, which is preferably the same type as the battery under test.

The battery testing apparatus preferably further includes terminals (VH) and (VL) configured to connect a battery under test therebetween, wherein the terminal (VL) is connected to the negative terminal of the SB; and a circuit block for voltage measurement (VM) configured to measure differential voltage between a reference voltage and the voltage of the battery under test, wherein the VM has a first lead connected to the terminal (VH) and a second lead connected to the positive terminal of the SB, wherein the reference voltage is determined on the basis of the voltage of the SB. A plurality of resistors are preferably included and configured to divide the voltage of the SB into a plurality of reference voltages within a range not greater than a value of the voltage of the SB. A circuit block for voltage measurement (VM) having a first lead connected to the terminal (VH) and a second lead connected to a multiplexer configured to select one from the reference voltages is preferably included, whereby the VM is configured to measure differential voltage between a programmable reference voltage and the voltage of the battery under test.

A battery analyzer for testing a battery has been disclosed, which includes: a normal battery operating as a standard battery (SB); a control circuit configured to apply a controllable current through the normal battery (Isb) that is equal to its self-discharge current, whereby a voltage of the normal battery is held constant at its open-circuit voltage (OCV); a first current sensor configured to measure the current through the SB and to provide feedback to control an output current (It) from the control circuit; a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision; and a first switch configured to connect or disconnect the current Isb and a second switch configured to connect or disconnect the current flowing to the positive terminal.

A battery analyzer may include a secondary rechargeable battery operating as a standard battery (SB); a galvanostat configured to apply a controllable current through the normal battery (Isb) that is equal to its self-discharge current, whereby a voltage of the normal battery is held constant at its open-circuit voltage (OCV); a first current sensor configured to measure the current through the SB and to provide feedback to control an output current (It) from the galvanostat, wherein a second current sensor is configured to measure the current It; a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision; and a first switch configured to connect or disconnect the current Isb and a second switch configured to connect or disconnect the current flowing to the positive terminal.

A differential battery analyzer (DBA) has been disclosed that includes a secondary rechargeable battery operating as a standard battery (SB); a galvanostat configured to apply a controllable current through the normal battery (Isb) that is equal to its self-discharge current, whereby a voltage of the normal battery is held constant at its open-circuit voltage (OCV); a first current sensor configured to measure the current through the SB and to provide feedback to control an output current (It) from the galvanostat, wherein a second current sensor is configured to measure the current It; a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision; a first switch configured to connect or disconnect the current Isb and a second switch configured to connect or disconnect the current flowing to the positive terminal; another two terminals (VH) and (VL) configured to connect a battery under test therebetween, wherein the terminal (VL) is connected to the negative terminal of the SB; and a circuit block for voltage measurement (VM) configured to measure differential voltage between a reference voltage and the voltage of the battery under test, wherein the VM has a first lead connected to the terminal (VH) and a second lead connected to the positive or negative terminal of the SB via a third switch, whereby the reference voltage is determined as the voltage of the SB or zero. The DBS preferably further includes a circuit block for current measurement (IM) configured to measure current of the battery under test via another two terminals (IH) and (IL); and a power supply.

### EMBODIMENTS OF THE PRESENT INVENTION

Embodiments of the present invention include the following.

In one aspect, the disclosure is directed to a method for measuring self-discharge current (I_{sd}) of cells in a group that are connected in parallel. The method comprises the steps of: applying a constant current (I_{O}) to a group of cells connected in parallel with each other; measuring current I_{b}# for at least one cell, wherein I_{b}# represents the current through the corresponding cell#; and calculating self-discharge current of at least one cell (denoted as I_{sd}#) from the equation: I_{sd}#=AI_{sd}−(I_{b}#−I_{O}In) on the assumption that the difference of dynamic capacitance (DNC) of all cells in the group can be ignored in calculation of self-discharge current and AI_{sd} is known, wherein AI_{sd} represents average self-discharge current of all cells in the group and n represents the number of cells in the group.

In another aspect, the disclosure is directed to a method for measuring self-discharge current (I_{sd}) of cells in a group that are connected in parallel. The method comprises the steps of: applying a constant current (I_{O}) to a group of cells connected in parallel with each other, wherein the absolute value of I_{O} is controlled to be equivalent to that of total self-discharge current (TI_{sd}) of the group of cells, and assuming TI_{sd} is known; measuring current I_{b}# for at least one cell, wherein I_{b}# represents the current through the corresponding cell#; and calculating self-discharge current of at least one cell (denoted as I_{sd}#) from the equation: I_{sd}#=−I_{b}# on the assumption that the difference of dynamic capacitance (DNC) of all cells in the group can be ignored in calculation of self-discharge current.

In another aspect, the disclosure is directed to a method for measuring self-discharge current (I_{sd}) of cells in a group that are connected in parallel. The method comprises the steps of: applying a constant voltage to a group of cells connected in parallel with each other to make a current (I_{O}) flowing through the group of cells; measuring current I_{b}# for at least one cell, wherein I_{b}# represents the current through the corresponding cell#; and calculating self-discharge current of at least one cell (denoted as Isd#) from the equation: I_{sd}#=−I_{b}#.

In one illustrative embodiment, the current (I_{O}) is applied using a differential battery analyzer (DBA). The DBA comprises: a normal battery operating as a standard battery (SB); a constant current source configured to apply a controllable current through the normal battery (I_{sb}) that is equal to its self-discharge current, whereby a voltage of the normal battery is held constant at its open-circuit voltage (OCV); and a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision.

In another aspect, the disclosure is directed to a method for measuring self-discharge current (I_{sd}) of cells in a group that are connected in series with an equalizer for each cell. The method comprises the steps of: allowing enough time for a group of cells connected in series to reach balance status, wherein each cell of the group is connected to an equalizer to keep the cells under same voltage with equalizers on, and wherein each equalizer has a fully bidirectional charge/discharge channel with at least two current ranges, and wherein at least one current range is low enough to be capable of measuring self-discharge current (SDC); measuring current I_{eqp}# for at least one equalizer in response to the cells' reaching balance status, wherein I_{eqp}# represents the current flowing through equalizer# connected to corresponding cell#; and calculating self-discharge current of at least one cell# (denoted as I_{sd}#) from an equation: I_{sd}#=−I_{eqp}#.

In another aspect, the disclosure is directed to a method for measuring self-discharge current (I_{sd}) of parallel cell groups (PCGs) that are connected in series with an equalizer for each PCG. The method comprises the steps of: allowing enough time for PCGs connected in series to reach balance status, wherein each PCG is connected to an equalizer to keep the PCGs under same voltage with equalizers on, and wherein each equalizer has a fully bidirectional charge/discharge channel with at least two current ranges, and wherein at least one current range is low enough to be capable of measuring self-discharge current (SDC); measuring current I_{eqp}# for at least one equalizer in response to the PCGs' reaching balance status, wherein I_{eqp}# represents the current flowing through equalizer# connected to corresponding PCG#; and calculating self-discharge current of at least one PCG# (denoted as I_{sd}#) from an equation: I_{sd}#=−I_{eqp}#.

In another aspect, the disclosure is directed to a method for using current of cells in a parallel group at open circuit condition as a quality control method used in forming and testing batteries. The method comprises the steps of: allowing enough time for a group of cells being tested to reach balance status, and measuring current I_{b}# flowing into corresponding cell#, wherein the group of cells are connected in parallel with each other but without connecting to any power supply to keep the group of cells in open circuit; and using the I_{b}# value as a standard for battery quality judgment and/or cell classification.

In one illustrative embodiment, the method further comprises the steps of: using abnormal distributed current through cell (I_{b}#) of a parallel battery group, at open circuit, as a criterion for cell safety judgment.

In another aspect, the disclosure is directed to a method for using current of cells in a parallel group as a quality control method used in forming and testing batteries. The method comprises the steps of: applying current to the cells connected in a parallel group; measuring current I_{b}# flowing into a corresponding cell#; and using abnormal distributed current through cell# (I_{b}#) of the parallel group as a criterion for cell safety judgment.

In another aspect, the disclosure is directed to a method for using current of cells in a parallel group at open circuit condition as a quality control method used in forming and testing batteries. The method comprises the steps of: allowing enough time for a group of cells being tested to reach balance status, and measuring current I_{b}# flowing into corresponding cell#, wherein the group of cells are connected in parallel with each other, but without connecting to any power supply to keep the group of cells in open circuit; using measured or statistically obtained average self-discharge current AI_{sd} of the parallel group to get a self-discharge current (I_{sd}#) of at least one cell#, according to I_{sd}#=AI_{sd}−I_{b}# derived from I_{b}#=AI_{sd}−I_{sd}#; and using the I_{sd}# value obtained as a standard for cell quality judgment and/or cell classification.

In another aspect, the disclosure is directed to an auto analyzer for evaluating batteries. The auto analyzer for evaluating batteries comprises a power supply, one or more processors and one or more storage media storing instructions executable by the one or more processors, wherein the instructions, when executed, cause the auto analyzer to perform operations according to any one of the methods described above.

In another aspect, the disclosure is directed to an equalizer plus (EQP) of a battery. The EQP of a battery comprises: a control circuit configured to apply a controllable current to a normal battery as a standard battery (SB) inside the EQP, wherein the current through the SB (I_{sb}) is controlled to be equal to its self-discharge current, whereby a voltage of the SB is kept constant at its open-circuit voltage (OCV); and two terminals (IOH) and (IOL) for connecting a battery under test therebetween, wherein the terminal (IOH) is connected to an end of a branch where the SB is located, and the voltage between the terminal (IOH) and the terminal (IOL) is kept at a constant value approximately equal to the voltage of the SB within a desired precision, and the terminal (IOL) is connected to the other end of the branch; and a fully bidirectional charge/discharge channel between the terminals (IOH) and (IOL) for measuring current, wherein the channel has at least two current ranges, and wherein at least one current range is low enough to be capable of measuring self-discharge current.

The embodiments described herein are merely examples for the sake of clarity and are not intended to limit the scope of the present invention. Other variations or modifications may be made by those skilled in the field of the above-described technology. There is no need and no way to describe all possible implementations of the principles of the difference measurement technology described herein. Obvious changes or variations resulting therefrom are still within the scope of the invention.

1. A method for measuring self-discharge of cells in a group of cells comprising the steps of:
measuring current I_{b}# for at least one cell in the group of cells, wherein I_{b}# represents the current through the corresponding cell#, wherein each cell in the group is connected serially with a sensor Rb# for measuring the current Ib#, thereby forming a branch that comprises a cell and a corresponding sensor, and wherein the branches are connected in parallel with one another; and
evaluating a self-discharge (I_{sd}#) of the at least one cell in the group of cells based on the current I_{b}#.

2. The method of claim 1, wherein evaluating the self-discharge of at least one cell in the group based on the current I_{b}# comprises the step of:
using the I_{b}# value as a standard for cell quality judgment and/or cell classification.

3. The method of claim 1, further comprising evaluating the group of cells to determine or estimate an average self-discharge current (AIsd) of the group of cells, wherein the evaluation includes:
comparing the measured current (Ib#) of the at least one cell to the average self-discharge current (AIsd) of the group to determine a difference; and
using the difference between measured current (Ib#) of the at least one cell and the average self-discharge current (AIsd) of the group to determine or estimate the self-discharge current (Isd#) of the at least one cell.

4. The method of claim 1, wherein prior to measuring current I_{b}# for at least one cell in the group of cells, the method further comprises the step of:
applying a constant current (I_{O}) to the group of cells.

5. The method of claim 4, wherein evaluating the self-discharge of at least one cell in the group of cells based on the current I_{b}# comprises the step of:
calculating self-discharge current of at least one cell# (denoted as I_{sd}#) from an equation: I_{sd}#=AI_{sd}−(I_{b}#−I_{O} In) on the assumption that a difference of dynamic capacitance (DNC) of the cells can be ignored in calculation of self-discharge current (I_{sd}) and AI_{sd} is known, wherein AI_{sd} represents average self-discharge current of all cells in the group and n represents a number of cells in the group.

6. The method of claim 5, wherein an absolute value of I_{O} is controlled to be equivalent to that of total self-discharge current (TI_{sd}) of the group of cells, and assuming TI_{sd} is known, the equation in claim 5 becomes: Isd#=−I_{b}# on the assumption that a difference of dynamic capacitance (DNC) of the cells can be ignored in calculation of self-discharge current.

7. The method of claim 1, further comprising the step of:
using abnormal distributed current through cell# (I_{b} #) of the group of cells as a criterion for cell safety judgment.

8. The method of claim 1, wherein prior to measuring current I_{b}# for at least one cell in the group of cells, the method further comprises the step of:
applying a constant voltage to the group of cells to make a current flow through the group of cells.

9. The method of claim 8, wherein evaluating the self-discharge of at least one cell in the group of cells based on the current I_{b}# comprises the step of:
calculating self-discharge current of at least one cell (denoted as I_{sd}#) from the equation: I_{sd}#=−I_{b}#.

10. The method of claim 1, wherein the group of cells are not connected to any power supply to keep in open circuit, and prior to measuring current I_{b}# for at least one cell in the group of cells, the method further comprises the step of:
allowing enough time for the group of cells to reach balance status.

11. The method of 10, wherein evaluating the self-discharge of at least one cell in the group based on the current I_{b}# comprises the step of:
using measured or statistically obtained average self-discharge current AI_{sd} of a parallel group to get self-discharge current (I_{sd}#) of at least one cell# according to I_{sd}#=AI_{sd}−I_{b}# derived from I_{b}#=AI_{sd}−I_{sd}#.

12. The method of claim 5, wherein the average self-discharge current AIsd of all cells in the group is calculated as:
$${A}_{/ sd} = {T}_{/ sd} / n ,$$
where:
T_{Isd} represents the total self-discharge current of the group of cells, and
n is the number of cells in the group of cells.

13. The method of claim 5, further comprising detecting an abnormal self-discharge current that deviates from the average self-discharge current of the group by more than a predefined threshold; and generating an indicator when an abnormal self-discharge current is detected.

14. A method for instant and continuous measurement and monitoring of self-discharge current of each and every cell in a group of cells, comprising the steps of:
connecting a number (N) of batteries that have a chemical and a mechanical structure and specifications that are the same within a desired precision level to form the group of cells, wherein each cell in the group is connected serially with a sensor Rb# for measuring the current through a corresponding cell#, thereby forming a branch that comprises a cell and a corresponding sensor, and wherein the branches are connected in parallel with one another;
assuming the N batteries have a certain average dynamic capacitance ADNC=sum(DNC(1):DNC(N))/N and a certain average dynamic leakage current ADNLC=sum(DNLC(1):DNLC(N))/N;
allowing the N batteries to reach an electrochemical balanced status;
assuming the cells in the group of cells have a chemical and a mechanical structure and specifications that are the same and have a constant ADNC and ADNLC within a desired precision level;
measuring each cell's leakage current by measuring current flow into each cell by corresponding sensor Rb# while the group of cells is under balanced status;
calculating DNLC(n)=ADNLC−I(n)+Ig/N, wherein I(n) is current flowing into a battery n measured by corresponding sensor Rbn and Ig is a total current flow into the group of cells; and
identifying a cell as defective based on an abnormal deviation of its self-discharge current from the average dynamic leakage current ADNLC.

15. An auto analyzer for evaluating batteries comprising:
a power supply;
one or more processors; and
one or more storage media storing instructions executable by the one or more processors, wherein the instructions, when executed, cause the auto analyzer to perform operations according to any one of claims 1, 3, 5, 9 and 11.

16. The auto analyzer for evaluating batteries of claim 15, wherein the power supply comprises a battery testing apparatus that comprises:
a normal battery operating as a standard battery (SB);
a constant current source configured to apply a controllable current through the normal battery (I_{sb}) that is equal to its self-discharge current, whereby a voltage of the normal battery is held constant at its open-circuit voltage (OCV); and
a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision.

17. The auto analyzer for evaluating batteries of claim 16, wherein the battery testing apparatus further comprises:
a fully bidirectional charge/discharge channel between the terminals (IOH) and (IOL) for measuring current, wherein the channel has at least two current ranges, wherein at least one current range is low enough to be capable of measuring self-discharge current, and wherein
the terminal (IOH) is connected to an end of a branch where the SB is located, and the terminal (IOL) is connected to the other end of the branch.

18. A battery testing apparatus comprising:
a power supply;
one or more processors;
a normal battery operating as a standard battery (SB);
a constant current source configured to apply a controllable current through the normal battery (I_{sb}) that is equal to its self-discharge current, whereby a voltage of the normal battery is held constant at its open-circuit voltage (OCV); and
a positive terminal (IOH) and a negative terminal (IOL) configured to connect a battery under test therebetween, wherein the voltage between the terminal (IOH) and the terminal (IOL) is kept at a constant value approximately equal to the voltage of the SB within a desired precision; and
one or more storage media storing instructions executable by the one or more processors, wherein the instructions, when executed, cause the battery testing apparatus to perform operations according to claim 14, thereby providing instant and continuous measurement and monitoring of self-discharge current of each and every cell in the parallel group of cells.

19. A method for measuring self-discharge of cells in a group of cells comprising the steps of:
evaluating the group of cells to determine or estimate an average self-discharge current (AI_{sd}) of the group of cells;
measuring current I_{b}# for at least one cell in the group of cells, wherein I_{b}# represents the current through the corresponding cell#; and
evaluating a self-discharge (I_{sd}#) of the at least one cell in the group of cells based on the current I_{b}#, wherein the evaluation includes:
comparing the measured current (I_{b}#) of the at least one cell to the average self-discharge current (AI_{sd}) of the group to determine a difference; and
using the difference between measured current (I_{b}#) of the at least one cell and the average self-discharge current (AI_{sd}) of the group to determine or estimate the self-discharge current (I_{sd}#) of the at least one cell.

20. The method of claim 19, wherein each cell in the group is connected serially with a sensor R_{b}# for measuring the current I_{b}#, thereby forming a branch that comprises a cell and a corresponding sensor, and wherein the branches are connected in parallel with one another.

21. The method of claim 19, wherein the average self-discharge current A_{Isd} of the group is calculated as:
$${A}_{/ sd} = {T}_{/ sd} / n ,$$
where:
T_{Isd} represents the total self-discharge current of the group of cells, and
n is the number of cells in the group of cells.

22. The method of claim 21, further comprising applying a constant current (I_{O}) to the group of cells prior to measuring the current I_{b}#.

23. The method of claim 19, wherein the group of cells are maintained at an open-circuit state, and wherein the method further comprises allowing enough time for the group of cells to reach balance status before measuring the current I_{b}#.

24. The method of claim 19, further comprising detecting an abnormal self-discharge current that deviates from the average self-discharge current of the group by more than a predefined threshold; and generating an indicator when an abnormal self-discharge current is detected.
